(19) United States
(12) Patent Application Publication
(10) Pub. No.: US 2026/0332916 A1
(43) Pub. Date: Oct. 22, 2026

(54) PHOTODETECTION DEVICE

(71) Applicant: Sony Semiconductor Solutions Corporation, Kanagawa (JP)

(72) Inventor: Jun Ogi, Tokyo (JP)

(21) Appl. No.: 19/115,591

(22) PCT Filed: Sep. 13, 2023
(86) PCT No.: PCT/JP2023/033391

§ 371 Date: Mar. 26, 2025

(30) Foreign Application Priority Data
Nov. 7, 2022 (JP) 2022-178319

(51) Int. Cl. H04N 25/78; H04N 25/773

(52) U.S. Cl. CPC H04N 25/78; H04N 25/773

(57) ABSTRACT

A light detecting device including a first photodiode; pixel readout circuitry coupled to the first photodiode, the pixel readout circuitry including a recharging circuit coupled to the photodiode and count rate control circuitry coupled between a node and a fixed voltage, the count rate control circuitry including a switch; and counter circuitry coupled to an output of the pixel readout circuitry, wherein the switch is configured to switch between a first counting mode and a second counting mode.

### CROSS REFERENCE TO RELATED APPLICATIONS

This application claims the benefit of Japanese Priority Patent Application JP 2022-178319 filed on Nov. 7, 2022, the entire contents of which are incorporated herein by reference.

### TECHNICAL FIELD

The present disclosure relates to a photodetection device.

### BACKGROUND ART

In a photon counting sensor, there is a technique of reducing the number of counts of photons by providing a pixel pause period in a case where entering light has high illuminance (PTL 1). In such a technique, photons of entering light with high illuminance are thinned out and detected, and the actual number of photons is calculated by statistical processing.

### CITATION LIST

### Patent Literature

PTL 1: JP 2020-123846A
PTL 2: WO 2022/018515A
PTL 3: JP 2018-157387A

### SUMMARY

### Technical Problem

However, because the photons of entering light are thinned out and detected, although the dynamic range is expanded, the number of photons at high illuminance may differ from the actual number of photons. In this case, a signal-noise ratio (SNR) deteriorates.

Therefore, the present disclosure provides a photodetection device capable of counting the number of photons of entering light at high illuminance with a high SNR.

### Solution to Problem

According to the present disclosure, there is provided a light detecting device including a first photodiode; pixel readout circuitry coupled to the first photodiode, the pixel readout circuitry including a recharging circuit coupled to the photodiode and count rate control circuitry coupled between a node and a fixed voltage, the count rate control circuitry including a switch; and
counter circuitry coupled to an output of the pixel readout circuitry, wherein the switch is configured to switch between a first counting mode and a second counting mode.

In some aspects, the first counting mode is a low-illuminance counting mode, and the second counting mode is a high-illuminance counting mode.

In some aspects, a counting rate of the counter in the low-illuminance mode is higher than a counting rate of the counter in the high-luminance mode.

In some aspects, a charge cycle of the first photodiode in a low-illuminance mode is longer than a charge cycle in the high-illuminance mode, in the low-illuminance mode, the counter circuitry increments a photon count value for each detected photon, in the high-illuminance mode, the counter circuitry increases the photon count value for each of a predetermined plurality of detected photons.

In some aspects, the pixel readout circuitry includes a resistor coupled between the first photodiode and the node.

In some aspects, the recharge circuitry includes a transistor connected between a voltage source and the resistor.

In some aspects, the transistor is configured to receive an external control signal that causes the transistor to recharge the first photodiode.

In some aspects, the pixel readout circuitry includes a first transistor coupled between the first photodiode and the node.

In some aspects, the recharge circuitry includes a second transistor connected between a voltage source and the first transistor.

In some aspects, the second transistor is configured to receive an external control signal that causes the second transistor to recharge the first photodiode.

In some aspects, the light detecting device further includes a second photodiode coupled to the pixel readout circuitry, wherein the first photodiode is connected in parallel with the second photodiode.

In some aspects, the pixel readout circuitry further includes a first capacitor coupled between the first photodiode and a reference voltage, a second capacitor coupled between the second photodiode and the reference voltage, a first transistor coupled between the first photodiode and the node, and a second transistor coupled between the second photodiode and the node.

In some aspects, the switch is configured to receive an external control signal that causes the switch to switch between the first counting mode and the second counting mode.

According to the present disclosure, there is also provided a first photodiode;
pixel readout circuitry coupled to the first photodiode, the pixel readout circuitry including a recharging circuit coupled to the photodiode and count rate control circuitry coupled between a node and a fixed voltage, the count rate control circuitry including a switch; and counter circuitry coupled to an output of the pixel readout circuitry, wherein the switch is configured to switch between a first counting mode and a second counting mode.

In some aspects, the first counting mode is a low-illuminance counting mode, and the second counting mode is a high-illuminance counting mode.

In some aspects, a counting rate of the counter in the low-illuminance mode is higher than a counting rate of the counter in the high-luminance mode.

### BRIEF DESCRIPTION OF DRAWINGS

FIG. 1 is a block diagram illustrating a configuration of a photodetection device according to a first embodiment.

FIG. 2 is a block diagram illustrating an example of an internal configuration of one pixel.

FIG. 3 is a timing diagram illustrating an operation example of a photodetection device according to the first embodiment.

FIG. 4 is a timing diagram illustrating an operation example of the photodetection device when the switch is in a conductive state.

FIG. 5 is a graph illustrating a relationship between the number of entering photons and a count value.

FIG. 6 is a block diagram illustrating a part of another example of the internal configuration of one pixel.

FIG. 7 is a block diagram illustrating an example of an internal configuration of a pixel according to a second embodiment.

FIG. 8 is a timing diagram illustrating an operation example of a photodetection device according to the second embodiment.

FIG. 9 is a timing diagram illustrating an operation example of the photodetection device when the switch enters the conductive state.

FIG. 10 is a block diagram illustrating an example of an internal configuration of a pixel according to a third embodiment.

FIG. 11 is a timing diagram illustrating an operation example of a photodetection device according to the third embodiment.

FIG. 12 is a timing diagram illustrating an operation example of the photodetection device when the switch enters the conductive state.

FIG. 13 is a block diagram illustrating an example of an internal configuration of a pixel according to a fourth embodiment.

FIG. 14 is a timing diagram illustrating an operation example of a photodetection device according to the fourth embodiment.

FIG. 15 is a timing diagram illustrating an operation example of the photodetection device according to the fourth embodiment.

FIG. 16 is a timing diagram illustrating an operation example of the photodetection device according to the fourth embodiment.

FIG. 17 is a timing diagram illustrating an operation example of the photodetection device according to the fourth embodiment.

FIG. 18 is a block diagram illustrating an example of an internal configuration of a pixel according to a fifth embodiment.

FIG. 19 is a timing diagram illustrating an operation example of a photodetection device according to the fifth embodiment.

FIG. 20 is a timing diagram illustrating an operation example of the photodetection device according to the fifth embodiment.

FIG. 21 is a conceptual diagram illustrating a charge cycle in the fifth embodiment.

FIG. 22 is a graph illustrating a relationship between a photon entry rate and a count value.

FIG. 23 is a graph illustrating a relationship between a photon entry rate and an SNR.

FIG. 24 is a block diagram illustrating an example of an internal configuration of a pixel according to a sixth embodiment.

FIG. 25 is a timing diagram illustrating an operation example of a photodetection device according to the sixth embodiment.

FIG. 26 is a timing diagram illustrating an operation example of the photodetection device according to the sixth embodiment.

FIG. 27 is a block diagram illustrating an example of an internal configuration of a pixel according to a seventh embodiment.

FIG. 28 is a timing diagram illustrating an operation example of a photodetection device according to the seventh embodiment.

FIG. 29 is a timing diagram illustrating an operation example of the photodetection device according to the seventh embodiment.

FIG. 30 is a timing diagram illustrating an operation example of the photodetection device according to the seventh embodiment.

FIG. 31 is a timing diagram illustrating an operation example of the photodetection device according to the seventh embodiment.

FIG. 32 is a block diagram illustrating an example of an internal configuration of a pixel according to an eighth embodiment.

FIG. 33 is a block diagram illustrating a part of an internal configuration example of a pixel according to a ninth embodiment.

FIG. 34A is a schematic view illustrating an example of a chip stack configuration of the photodetection device.

FIG 34B is a schematic view illustrating an example of a chip stack configuration of the photodetection device.

FIG. 35 is a block diagram illustrating an example of a schematic configuration of a vehicle control system.

FIG. 36 is an explanatory diagram illustrating an example of installation positions of a vehicle exterior information detector and an imaging part.

FIG. 37 is a block diagram illustrating a schematic configuration example of an electronic apparatus to which an optical device according to an existing technology is applied.

### DESCRIPTION OF EMBODIMENTS

Hereinafter, specific embodiments to which the present technology is applied will be described in detail with reference to the drawings. The drawings are schematic or conceptual, and the ratio of each portion and the like are not necessarily the same as actual ones. In the specification and the drawings, similar elements as those described above concerning the previously described drawings are denoted by the same reference signs, and the detailed description thereof is appropriately omitted.

### First Embodiment

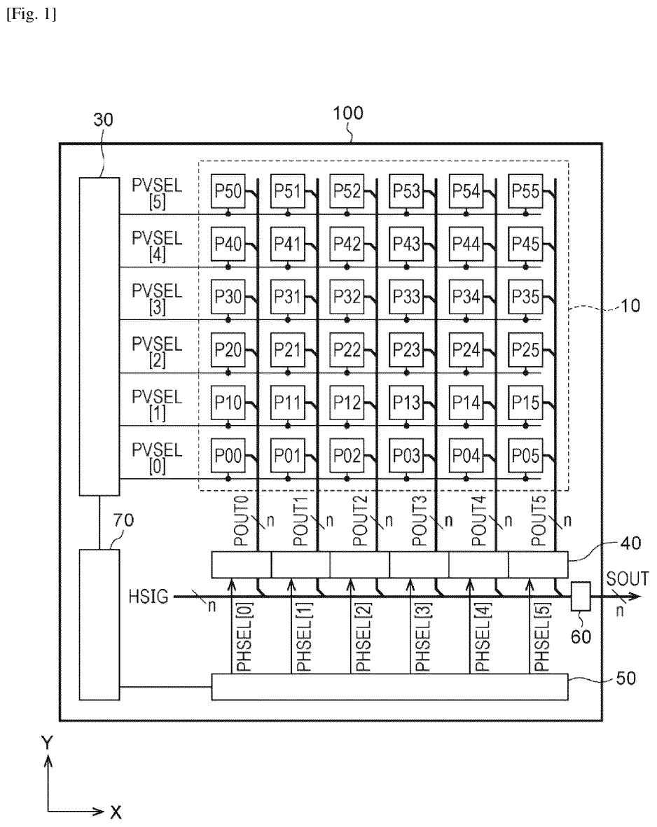

FIG. 1 is a block diagram illustrating a schematic configuration of a photodetection device according to a first embodiment.

A photodetection device 100 according to the present embodiment includes a pixel region 10, a vertical selection circuit 30, a signal processing circuit 40, a horizontal selection circuit 50, an output circuit 60, and a control circuit 70.

The pixel region 10 is provided with a plurality of pixels P two-dimensionally arranged in a matrix in the row direction and the column direction. FIG. 1 illustrates 36 pixels P arranged in six rows from the zeroth row to the fifth row and six columns from the zeroth column to the fifth column, together with reference signs indicating row numbers and column numbers. For example, the pixels P arranged in the first row and the fourth column are denoted by reference sign P14.

Note that the number of rows and the number of columns of the pixel array constituting the pixel region 10 are not particularly limited. Further, the pixels P are not necessarily arranged two-dimensionally in the pixel region 10. For example, the pixel region 10 may include one pixel P, or the pixels P may be arranged one-dimensionally in the row direction or the column direction in the pixel region 10. Furthermore, the pixels P may be arranged three-dimensionally. The pixel region 10 may be configured as a stack formed by stacking a plurality of substrates on which the pixels P are formed.

In each row of the pixel array of the pixel region 10, a control line PVSEL extending in the X direction is provided. The control line PVSEL is connected to each of the plurality of pixels P arranged in the X direction and forms a signal line common to these pixels P. The X direction in which the control line PVSEL extends may be referred to as a row direction or a horizontal direction. Note that in FIG. 1, the control line PVSEL is represented together with reference sign indicating a row number. For example, the control line in the first row is denoted by reference sign PVSEL [1].

The control line PVSEL in each row is connected to the vertical selection circuit 30. The vertical selection circuit 30 is a circuit part that supplies the pixel P with a control signal for driving a signal generation circuit (not illustrated) in the pixel P via the control line PVSEL. The vertical selection circuit 30 controls the start and end of a period in which the counter included in the pixel P integrates counts.

In each column of the pixel array of the pixel region 10, an output line POUT extending in the Y direction intersecting (e.g., orthogonal to) the X direction is provided. The output line POUT is connected to each of the plurality of pixels P arranged in the Y direction and forms a signal line common to these pixels P. The Y direction in which the output line POUT extends may be referred to as a column direction or a vertical direction. Note that in FIG. 1, the output line POUT is represented together with reference sign indicating a column number. For example, the output line of the fourth column is denoted by reference sign POUT4. Each of the output lines POUT includes n signal lines for outputting an n-bit digital signal.

The output line POUT is connected to the signal processing circuit 40. The signal processing circuit 40 is provided corresponding to each column of the pixel array of the pixel region 10 and is connected to the output line POUT in the corresponding column. The signal processing circuit 40 has a function of holding a signal output from the pixel P via the output line POUT in the corresponding column. Since the signal output from the pixel P is an n-bit signal input via the n signal lines of the output line POUT, each of the signal processing circuits 40 includes at least n holders to hold signals of the respective bits.

The horizontal selection circuit 50 is a circuit part that supplies the signal processing circuit 40 with a control signal for reading a signal from the signal processing circuit 40. The horizontal selection circuit 50 supplies a control signal to the signal processing circuit 40 in each column via a control line PHSEL. The signal processing circuit 40 having received the control signal from the horizontal selection circuit 50 outputs the signal held in the holder to the output circuit 60 via a horizontal output line HSIG. Note that in FIG. 1, the control line PHSEL is represented together with reference sign indicating a column number. For example, the control line in the fourth column is denoted by reference sign PHSEL[4]. The horizontal output line HSIG includes n signal lines for outputting an n-bit digital signal.

The output circuit 60 is a circuit part for outputting a signal supplied via the horizontal output line HSIG to the outside of the photodetection device 100 as an output signal SOUT. The control circuit 70 is a circuit part for supplying control signals for controlling the operations and timings of the vertical selection circuit 30, the signal processing circuit 40, the horizontal selection circuit 50, and the output circuit 60. Note that at least one or some of the control signals for controlling the operations and timings of the vertical selection circuit 30, the signal processing circuit 40, the horizontal selection circuit 50, and the output circuit 60 may be supplied from the outside of the photodetection device 100.

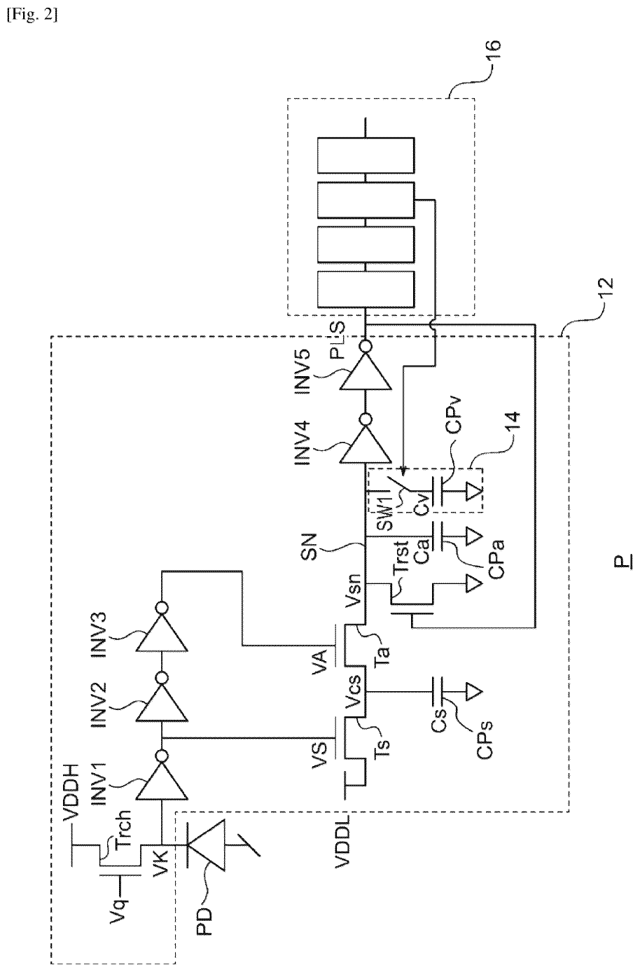

FIG. 2 is a block diagram illustrating an example of an internal configuration of one pixel P. Each pixel P includes an avalanche multiplication type photodiode PD, a pixel control circuit 12, a count rate control circuit 14, and a counter circuit 16.

The anode of the photodiode PD is connected to a reference voltage source. The reference voltage source is, for example, a ground or a negative voltage source. The cathode of the photodiode PD is connected to a source of a transistor Trch of the pixel control circuit 12. When a reverse bias voltage applied between the anode and the cathode is higher than or equal to a breakdown voltage, the photodiode PD undergoes avalanche breakdown upon receipt of the entry of photons and generates a multiplied avalanche current. The avalanche current flows through the photodiode PD to cause the cathode voltage of the photodiode PD to change. With the change in the cathode voltage, the pixel control circuit 12 changes an output signal of an inverter INV5 and outputs a light detection pulse PLS to the counter circuit 16. The photodiode PD is, for example, a single photon avalanche diode (SPAD) that undergoes avalanche breakdown once due to the entry of one photon.

The pixel control circuit 12 includes transistors Trch, Ts, Ta, and Trst, inverters INV1 to INV5, capacitors CPs, CPa, and the count rate control circuit 14.

The transistor Trch is connected between a high-level voltage source VDDH and the cathode of the photodiode PD. The drain of the transistor Trch is connected to the voltage source VDDH, and the source thereof is connected to the cathode of the photodiode PD and the input of the inverter INV1. The transistor Trch has a gate connected to one of the control lines PVSEL, and the gate receives a control signal Vq from the vertical selection circuit 30.

By the transistor Trch entering a conductive state, the cathode of the photodiode PD is charged by the voltage source VDDH. As a result, a reverse bias voltage is applied to the photodiode PD. When the transistor Trch enters a non-conductive state, the photodiode PD is held with the reverse bias voltage applied, and waits for entry of a photon. At this time, the cathode voltage of the photodiode PD is VK. As described above, the transistor Trch is used for charging and recharging the photodiode PD. The transistor Trch may be, for example, an n-type metal-oxide-semiconductor field-effect transistor (MOSFET).

The inverters INV1 to INV3 are connected in series between the cathode of the photodiode PD and the gate of the transistor Ta. Further, the output of the inverter INV1 is connected to the gate of the transistor Ts. The inverters INV1 to INV3 each function as a buffer and a delay circuit.

The transistor Ts is connected between a voltage source VDDL and a sense node SN. The voltage source VDDL is a voltage source lower than the voltage source VDDH but higher than the reference voltage source. The drain of the transistor Ts is connected to the voltage source VDDL, and the source thereof is connected to the drain of the transistor Ta and one end of the capacitor CPs. The transistor Ts has a gate connected to the output of the inverter INV1, and the gate receives the inversion voltage VS of the voltage VK. The transistor Ts is controlled to be in the conductive state by the avalanche breakdown of the photodiode PD.

The transistor Ts is in the non-conductive state in a case where the cathode voltage of the photodiode PD is at a charged level, and electrically disconnects one end of the capacitor CPs from the voltage source VDDL. When avalanche breakdown occurs in the photodiode PD and the cathode voltage VK decreases, the transistor Ts enters the conductive state, and the capacitor CPs is charged by the voltage source VDDL. The voltage of the capacitor CPs is Ves. The transistor Ts may be, for example, an n-type MOSFET.

The transistor Ta is connected between the transistor Ts and the sense node SN. The drain of the transistor Ta is connected to the source of the drain of the transistor Ts and one end of the capacitor CPs, and the source thereof is connected to the sense node SN. The transistor Ta has a gate connected to the output of the inverter INV3, and the gate receives an inversion voltage VA of the voltage VK. The voltages VS and VA are signals of the same logic (voltages of the same level). However, since the voltage VA passes through the inverters INV2 and INV3, the voltage VA is input to the gate of the transistor Ta with a delay relative to the voltage VS that is input to the gate of the transistor Ts. Therefore, the transistor Ta enters the conductive state later than the transistor Ts due to the avalanche breakdown of the photodiode PD.

The transistor Ta is in the non-conductive state in a case where the cathode voltage VK of the photodiode PD is at the charged level, and electrically disconnects one end of the capacitor CPs and the sense node SN. When the photodiode PD receives a photon and undergoes avalanche breakdown, and the cathode voltage VK decreases, the transistor Ts temporarily enters the conductive state. Thereby, the capacitor CPs is charged by the voltage source VDDL. When the voltage VK is restored to the charged level by the quenching of the photodiode PD, the transistor Ts returns to the non-conductive state. After the transistor Ts returns to the non-conductive state, the transistor Ta enters the conductive state. Thereby, the sense node SN is charged by the capacitor CPs. The transistor Ta may be, for example, an n-type MOSFET.

The transistor Trst is connected between the sense node SN and a reference voltage source (e.g., ground). The drain of the transistor Trst is connected to the sense node SN and the source thereof is connected to a reference voltage source. That is, the transistor Trst has a gate connected to the output of the inverter INV5 (i.e., the output of the pixel control circuit 12), and the gate receives the light detection pulse PLS.

The transistor Trst is in the non-conductive state when the light detection pulse PLS is not output, and enters the conductive state every time the light detection pulse PLS is output to the counter circuit 16. By the transistor Trst entering the conductive state, the voltage Vsn of the sense node SN is reset to the reference voltage (e.g., the ground voltage). However, the light detection pulse PLS is delayed and output via the inverters INV4 and INV5 with respect to the change in the sense node SN. Thus, the transistor Trst can reset the voltage Vsn of the sense node SN after a sufficient change in the voltage Vsn of the sense node SN. The transistor Trst may be, for example, an n-type MOSFET.

The capacitor CPs is a fixed capacitance connected between a node between the transistor Ts and the transistor Ta and a reference voltage source (e.g., ground). The capacitor CPs includes a parasitic capacitance of a node between the transistor Ts and the transistor Ta. The capacitor CPs is charged by the voltage source VDDL when the transistor Ts is in the conductive state. In addition, when the transistor Ta enters the conductive state, the capacitor CPs charges the sense node SN. The capacitance Cs of the capacitor CPs is set to a predetermined value.

The capacitor CPa is a fixed capacitance connected between the sense node SN and the reference voltage source. The capacitor CPa includes the parasitic capacitance of the sense node SN. The capacitor CPa is charged by the capacitor CPs when the transistor Ta is in the conductive state. On the other hand, the capacitor CPa is discharged and reset when the transistor Trst is in the conductive state. A capacitance Ca of the capacitor CPa is also set to a predetermined value.

The count rate control circuit 14 includes a capacitor CPv and a switch SW1 connected in series between the sense node SN and a reference voltage source (e.g., ground). The switch SW1 is connected between the sense node SN and one end of the capacitor CPv. The switch SW1 may be a transistor controlled by the counter circuit 16. The capacitor CPv is a fixed capacitance connected between the switch SW1 and the reference voltage source. The capacitance Cv of the capacitor CPv is set to a predetermined value.

The switch SW1 is controlled by a control signal from a predetermined bit of the counter circuit 16. For example, the switch is in the non-conductive state in a case where the count value is less than a predetermined value, and the switch is in the conductive state in a case where the count value is greater than or equal to the predetermined value. In a case where the count value is less than the predetermined value and the switch SW1 is in the non-conductive state, the capacitance of the sense node SN is Ca. At this time, one light detection pulse PLS is output every time the photodiode PD undergoes avalanche breakdown (detects one photon) once.

On the other hand, when the number of counts of the counter circuit 16 reaches a predetermined value and the corresponding predetermined bit is inverted, the switch SW1 enters the conductive state. Thereby, the capacitor CPv is connected in parallel to the capacitor CPa, and the capacitance of the sense node SN increases from Ca to Ca+Cv. As a result, one light detection pulse PLS is output every time the photodiode PD undergoes avalanche breakdown (detects a plurality of photons) a plurality of times.

In this manner, the count rate control circuit 14 changes the capacitance of the sense node SN according to the count value of the counter circuit 16, and controls the number of breakdown times of the photodiode PD necessary for increasing the count value by 1.

The counter circuit 16 is connected to the output of the inverter INV5 (the output of the pixel control circuit 12). The counter circuit 16 counts the light detection pulse PLS on the basis of the voltage Vsn of the sense node SN. That is, the counter circuit 16 counts the number of breakdown times of the photodiode PD. The counter circuit 16 may be, for example, a register circuit that integrates the rise of the light detection pulse PLS. In a case where the count value is less than the predetermined value, the counter circuit 16 increases the count value by 1 every time the switch SW1 is brought into the non-conductive state and the photodiode PD detects one photon. When the count value reaches the predetermined value and the predetermined bit of the counter circuit 16 is inverted, the counter circuit 16 inverts the control signal of the switch SW1 to bring the switch SW1 into the conductive state. Thus, as described above, the counter circuit 16 increases the count value by 1 every time the photodiode PD detects a plurality of photons.

Next, the operation of the photodetection device according to the first embodiment will be described.

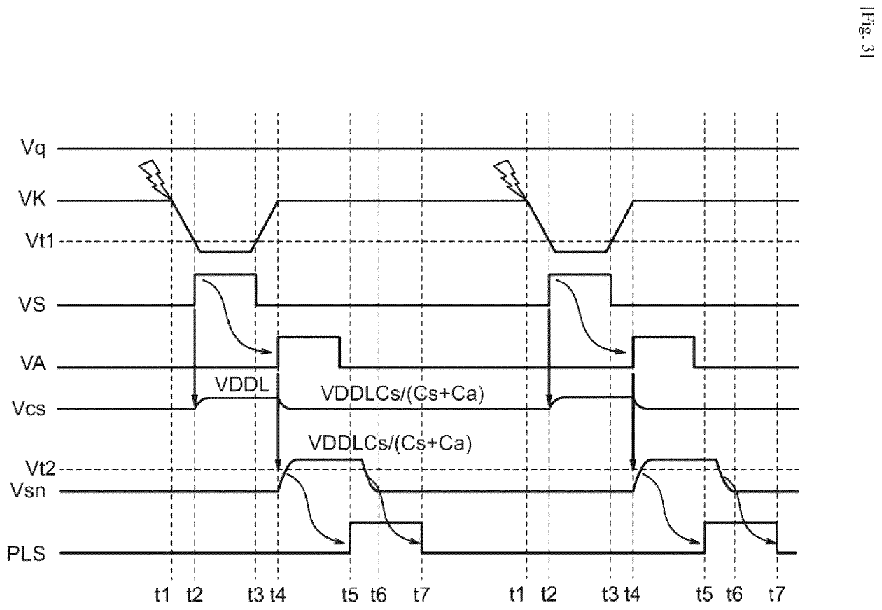

FIG. 3 is a timing diagram illustrating an operation example of the photodetection device according to the first embodiment. In FIG. 3, the switch SW1 is in the non-conductive state, and the capacitance of the sense node SN is Ca, which is relatively small. This operation is an operation suitable for a low-illuminance mode for detecting low-illuminance light.

First, during photon standby before t1, the control signal Vq is set to the high-level voltage, and the transistor Trch is in the conductive state. As a result, the cathode of the photodiode PD is charged by the high-level voltage source VDDH, and the cathode voltage VK increases. A reverse bias voltage is applied to the photodiode PD. In such a state, the photodiode PD waits for entry of a photon.

At t1, when a photon enters the photodiode PD, avalanche breakdown occurs in the photodiode PD, and the cathode voltage VK decreases.

At t2, when the cathode voltage VK falls below a threshold Vt1, a voltage Vs rises.

This brings the transistor Ts into the conductive state, and the capacitor CPs is charged by the voltage source VDDL via the transistor Ts. The voltage Vcs is substantially equal to the voltage of the voltage source VDDL.

Since the transistor Trch remains in the conductive state, when the photodiode PD returns to the original state before breakdown due to quenching, the cathode voltage VK still increases.

At t3, when the cathode voltage VK exceeds the threshold Vt1, the gate voltage VS of the transistor Ts falls. As a result, the transistor Ts into the non-conductive state, and the capacitor CPs is disconnected from the voltage source VDDL while being in the charged state.

After the voltage Vs falls, the voltage VA is delayed from the voltage VS and rises due to the delay circuits of the inverters INV2 and INV3. After the gate voltage VS falls, the gate voltage VA rises at t4. This brings the transistor Ta into the conductive state, and the capacitor CPs and the capacitor CPa are connected in parallel between the sense node SN and the reference voltage source. Some of the charges accumulated in the capacitor CPs move to the capacitor CPa, and the voltage Vsn of the sense node SN and the voltage Vcs of the capacitor CPs become substantially equal.

At this time, both the voltages Vcs, Vsn satisfy Expression 1.

Vcs=Vsn=VDDL×(Cs/(Cs+Ca)) (Expression 1)

When the voltage Vsn of the sense node SN exceeds a threshold Vt2, the light detection pulse PLS rises at t5. After the voltage Vsn exceeds the threshold Vt2, the light detection pulse PLS is delayed and rises due to the delay circuits of the inverters INV4 and INV5.

The counter circuit 16 counts the rise of the light detection pulse PLS.

The rise of the light detection pulse PLS is fed back to the gate of the transistor Trst. Thereby, at t6, the transistor Trst enters the conductive state, and the voltage Vsn of the sense node SN is reset by the reference voltage source. Furthermore, when the voltage Vsn of the sense node SN is reset by the reference voltage source, the light detection pulse PLS falls at t7.

Thereafter, the operation from the operation from t1 to t7 is repeated every time a photon enters the photodiode PD.

Here, in FIG. 3, the switch SW1 is in the non-conductive state, and the capacitance of the sense node SN is Ca, which is relatively small. Therefore, when the transistor Ta enters the conductive state at t4 to t5, the voltage Vcs is subjected to capacitance division between the capacitor CPs and the capacitor CPa. The voltage Vsn of the sense node SN is determined by a ratio Cs/(Cs+Ca) between the capacitance of the capacitor CPs (the capacitance of the node between the transistor Ts and the transistor Ta) and the capacitance of the capacitor CPa (the capacitance of the sense node SN), and is expressed as Expression 1. In a case where the capacitance Ca is small, the voltage Vsn of the sense node SN increases. When the capacitance Ca of the capacitor CPa is set so that the voltage Vsn of the sense node SN at this time exceeds the threshold Vt2, the light detection pulse PLS is generated at every avalanche breakdown of the photodiode PD. Thus, the counter circuit 16 can perform counting every time one photon enters the photodiode PD. That is, the counter circuit 16 can count the number of photons entering the photodiode PD.

When the number of counts of photons reaches a predetermined value, a predetermined bit of the counter circuit 16 is inverted. At this time, the counter circuit 16 inverts the control signal of the switch SW1 to bring the switch SW1 into the conductive state.

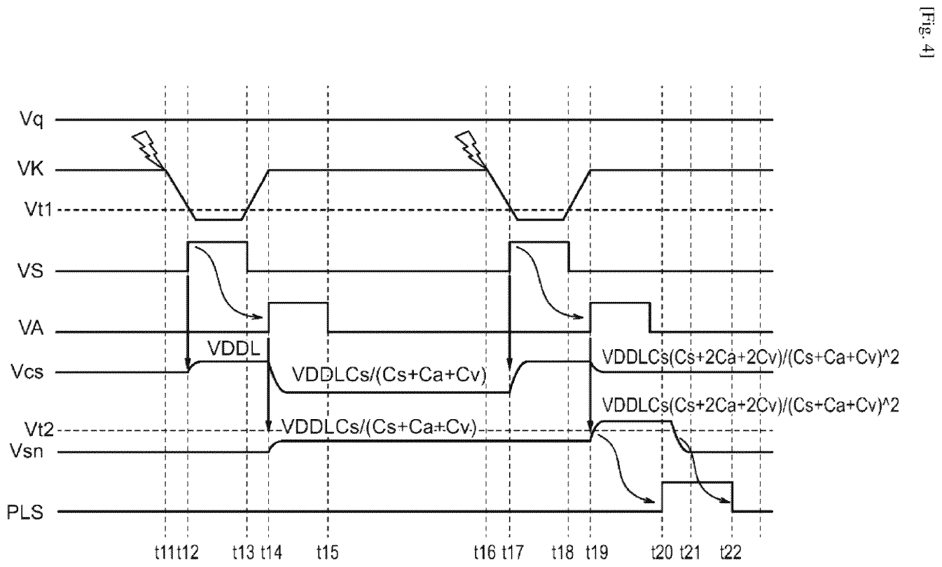

FIG. 4 is a timing diagram illustrating an operation example of the photodetection device when the switch SW1 enters the conductive state. In FIG. 4, the switch SW1 is in the conductive state, and the capacitance of the sense node SN is (Ca+Cv), which is relatively large. This operation is an operation suitable for a high-illuminance mode for detecting high-illuminance light.

During photon standby, the control signal Vq is set to the high-level voltage, and the transistor Trch is in the conductive state. The cathode voltage VK of the photodiode PD is at the charged level by the high-level voltage source VDDH. A reverse bias voltage is applied to the photodiode PD. In such a state, the photodiode PD waits for entry of a photon.

At t11, when a photon enters the photodiode PD, avalanche breakdown occurs in the photodiode PD, and the cathode voltage VK decreases.

At t12, when the cathode voltage VK falls below the threshold Vt1, the voltage VS rises.

This brings the transistor Ts into the conductive state, and the capacitor CPs is charged by the voltage source VDDL via the transistor Ts. The voltage Vcs is substantially equal to the voltage of the voltage source VDDL.

Since the transistor Trch remains in the conductive state, when the photodiode PD returns to the original state before breakdown due to quenching, the cathode voltage VK still increases.

At t13, when the cathode voltage VK exceeds the threshold Vt1, the gate voltage VS of the transistor Ts falls. As a result, the transistor Ts into the non-conductive state, and the capacitor CPs is disconnected from the voltage source VDDL while being in the charged state.

After the voltage VS falls, the voltage VA is delayed from the voltage VS and rises due to the delay circuits of the inverters INV2 and INV3. After the gate voltage VS falls, the gate voltage VA rises at t14. This brings the transistor Ta into the conductive state, and the capacitors CPs, CPa, CPv are connected in parallel between the sense node SN and the reference voltage source. Some of the charges accumulated in the capacitor CPs move to the capacitors CPa, CPv, and the voltage Vsn of the sense node SN and the voltage Vcs of one end of the capacitor CPs become substantially equal. At this time, both the voltages Vcs, Vsn satisfy Expression 2.

Vcs=Vsn=VDDL×(Cs/(Cs+Ca+Cv)) (Expression 2)

Here, with the switch SW1 in the conductive state, the capacitance of the sense node SN increases from Ca to (Ca+Cv). Therefore, from t14 to t15, the voltage Vcs is subjected to capacitance division between the capacitor CPs and the capacitors CPa, CPv. As a result, the voltage Vsn of the sense node SN is determined by a ratio Cs/(Cs+Ca+Cv) between the capacitance of the capacitor CPs (the capacitance of the node between the transistor Ts and the transistor Ta) and the capacitances of the capacitors CPa, CPv (the capacitance of the sense node SN), and is expressed as Expression 2. The capacitance (Ca+Cv) is larger than the capacitance Ca, and hence the voltage Vsn of the sense node SN is smaller than that when the switch SW1 is in the non-conductive state. When the capacitances Ca, Cv of the capacitors CPa, CPv are set so that the voltage Vsn of the sense node SN at this time does not exceed the threshold Vt2, the light detection pulse PLS is not generated at the first avalanche breakdown of the photodiode PD. That is, even when one photon enters the photodiode PD, the counter circuit 16 does not perform counting.

Since the light detection pulse PLS is not generated, the transistor Trst remains in the non-conductive state, and the voltage Vsn of the sense node SN is not reset.

After the gate voltage VA falls at t15, when the second photon enters the photodiode PD at t16, avalanche breakdown occurs in the photodiode PD, and the cathode voltage VK decreases again as in the operation at t11.

The operations of t17 to t18 are the same as the operations of t12 to t13, respectively.

At t18, after the voltage VS falls, the voltage VA is delayed from the voltage VS and rises due to the delay circuits of the inverters INV2 and INV3. After the gate voltage VS falls, the gate voltage VA rises at t19. This brings the transistor Ta into the conductive state, and the capacitors CPs, CPa, CPv are electrically connected in parallel. Some of the charges accumulated in the capacitor CPs further move to the capacitors CPa, CPv, and the voltage Vsn of the sense node SN and the voltage Vcs of the capacitor CPs are averaged and become approximately equal. At this time, both the voltages Vcs, Vsn satisfy Expression 3.

Vcs=Vsn=VDDL×(Cs×(Cs+2Ca+2Cv)/(Cs+Ca+Cv)²) (Expression 3)

Here, the sense node SN has not been reset because the light detection pulse PLS was not generated at the entry of the first photon. Therefore, the voltage Vsn of the sense node SN remains at a charged level of VDDL×(Cs/(Cs+Ca+Cv)). Furthermore, at the entry of the second photon, the sense node SN is further charged, and the voltage Vsn of the sense node SN becomes VDDL×(Cs×(Cs+2Ca+2Cv)/(Cs+Ca+Cv)²). When the capacitances Ca, Cv of the capacitors CPa, CPv are set so that the voltage Vsn of the sense node SN at this time exceeds the threshold Vt2, the light detection pulse PLS is generated by the second avalanche breakdown of the photodiode PD. Thus, the counter circuit 16 can count 1 every time two photons enter the photodiode PD.

In order for the counter circuit 16 to count 1 for detection of one photon, Cs and Ca are set so as to satisfy Expression 4. In order for the counter circuit 16 to count 1 with respect to the detection of two photons, Cs, Ca, and Cv are set so as to satisfy Expressions 5 and 6. Note that Vth is the threshold voltage of the inverter INV4.

Ca<Cs (VDDL−Vth)/Vth (Expression 4)

Ca+Cv>Cs (VDDL−Vth)/Vth (Expression 5)

VDDL×Cs (Cs+2Ca+sCv)>Vth (Cs+Ca+Cv)² (Expression 6)

At t20, when the light detection pulse PLS rises, the counter circuit 16 increases the count value by 1 and raises the control signal to the transistor Trst. Thereby, at t21, the transistor Trst enters the conductive state, and the voltage Vsn of the sense node SN is reset by the reference voltage source. Furthermore, when the voltage Vsn of the sense node SN is reset by the reference voltage source, the light detection pulse PLS falls at t22.

Thereafter, the operation from t11 to t22 is repeated every time two photons enter the photodiode PD.

As described above, the photodetection device 100 according to the present embodiment can control an increase in the count value with respect to the number of breakdown times of the photodiode PD according to the count value of the counter circuit 16.

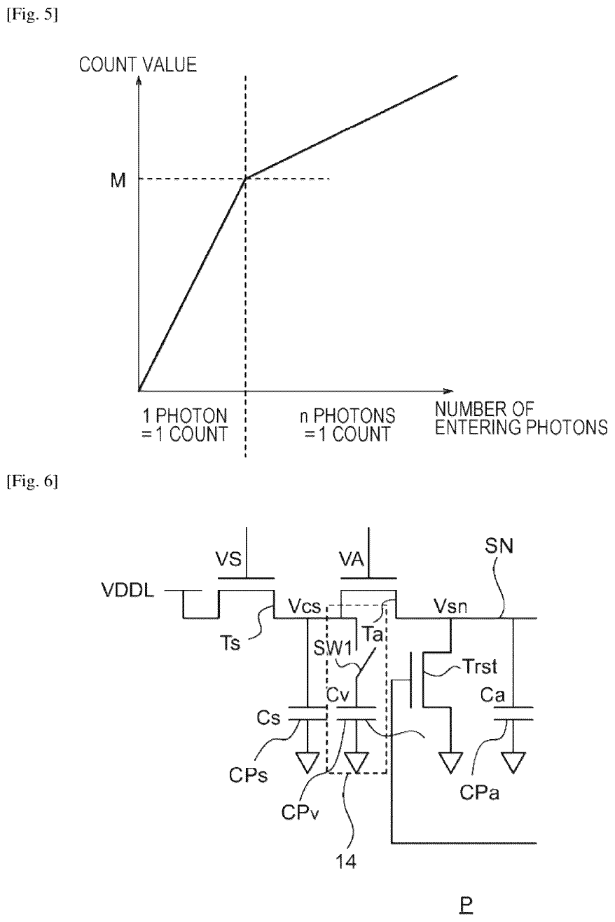

For example, FIG. 5 is a graph illustrating a relationship between the number of entering photons and the count value. The horizontal axis represents the number of photons entering the photodiode PD. The vertical axis represents the count value of the counter circuit 16.

In a case where the count value of the counter circuit 16 is less than a predetermined value M (in the case of low-illuminance light), the switch SW1 of the count rate control circuit 14 is in the non-conductive state and electrically disconnects the capacitor CPv from the sense node SN. Hence the capacitance of the sense node SN is relatively small as Ca, and the voltage Vsn of the sense node SN greatly increases due to the charges from the capacitor CPs. As a result, the pixel control circuit 12 outputs the light detection pulse PLS every time avalanche breakdown occurs in the photodiode PD. The counter circuit 16 increases the count value by 1 every time the photodiode PD detects one photon.

On the other hand, in a case where the count value of the counter circuit 16 is greater than or equal to the predetermined value M (in the case of high-illuminance light), the switch SW1 of the count rate control circuit 14 enters the conductive state and electrically connects the capacitor CPv to the sense node SN. Hence the capacitance of the sense node SN increases from Ca to (Ca+Cv), and the rise width of the voltage Vsn of the sense node SN decreases due to the charges from the capacitor CPs. As a result, the pixel control circuit 12 outputs the light detection pulse PLS every time avalanche breakdown occurs in the photodiode PD a plurality of times. The counter circuit 16 increases the count value by 1 every time the photodiode PD detects a plurality of photons.

Note that in a case where the switch SW1 is in the conductive state, the counter circuit 16 increases the count value by 1 every time the photodiode PD detects two photons. By changing the capacitance Cv of the capacitor CPv, the counter circuit 16 can increase the count value by 1 every time the photodiode PD breaks down n times (n is an integer of 2 or more) (every time n photons are detected).

As described above, according to the present embodiment, the capacitance of the sense node SN is controlled while the photodiode PD detects all entering photons, whereby it is possible to limit the generation frequency of the light detection pulse PLS and reduce the count value of the counter circuit 16.

For example, upon entry of low-illuminance light, the counter circuit 16 increases the count value for one photon. As a result, the photodetection device 100 can detect low-illuminance light at a high SNR.

Upon entry of high-illuminance light, the counter circuit 16 increases the count value for one photon until the count value reaches the predetermined value M, and increases the count value for n photons when the count value exceeds the predetermined value M. Thus, even with high-illuminance light, an increase in the count value (bit depth) of the counter circuit 16 is reduced, and the counter value is less likely to reach its upper limit. This can further reduce the count value of the counter circuit 16. Therefore, the counter circuit 16 is less likely to be saturated with high-illuminance light and can count the number of photons of light having higher illuminance.

Further, even with high-illuminance light, the photodiode PD does not thin out and detects all photons, and the number of photons can be accurately calculated with reference to the count value of the counter circuit 16. That is, even upon entry of high-illuminance light, the counter circuit 16 can count photons without causing deterioration in the SNR. Therefore, the photodetection device 100 according to the present embodiment can expand the dynamic range without causing deterioration in the SNR.

Further, even with high-illuminance light, the count value reaches its upper limit less frequently, enabling reduction in the number of reading times of the counter circuit 16. Moreover, in the high-illuminance light, the generation of the count value of the counter circuit 16 and the light detection pulse PLS is reduced. This makes it possible to reduce the power consumption of the photodetection device 100

The count rate control circuit 14 is provided corresponding to each pixel P. Therefore, the count rate control circuit 14 can switch the sensitivity to either the low-illuminance mode or the high-illuminance mode for each pixel P.

The reduction in the bit depth of the register circuit of the counter circuit 16 also leads to reduction in the layout area of each pixel P.

In addition, the count rate control circuit 14 may be controlled from the outside of the photodetection device 100. In this case, it is possible to switch the entire pixel region 10, although switching for each pixel P is difficult.

### Modification

FIG. 6 is a block diagram illustrating a part of another example of the internal configuration of one pixel P. In the first embodiment, the count rate control circuit 14 changes the capacitance of the sense node SN by the capacitor CPv. However, as in the present modification, the count rate control circuit 14 may be connected in parallel to the capacitor CPs to make the capacitance of the node between the transistor Ts and the transistor Ta variable. In this case, in the low-illuminance mode, the count rate control circuit 14 brings the switch SW1 into the conductive state, electrically connects the capacitor CPv to the capacitor CPs in parallel, and increases the capacitance of the node between the transistor Ts and the transistor Ta. In the high-illuminance mode, the count rate control circuit 14 brings the switch SW1 into the non-conductive state, electrically disconnects the capacitor CPv from the capacitor CPs, and reduces the capacitance of the node between the transistor Ts and the transistor Ta. Similarly to the above embodiment, the switch SW1 is only required to be controlled by a control signal from the counter circuit 16. Note that the control signal of the switch SW1 is a reversed logic from that of the first embodiment. As a result, similarly to the above embodiment, the photodetection device 100 can control an increase in the count value with respect to the number of breakdown times of the photodiode PD according to the count value of the counter circuit 16.

Other configurations and operations of the present modification may be the same as those of the first embodiment. Thus, the present modification can obtain the effects similar to those of the first embodiment.

### Second Embodiment

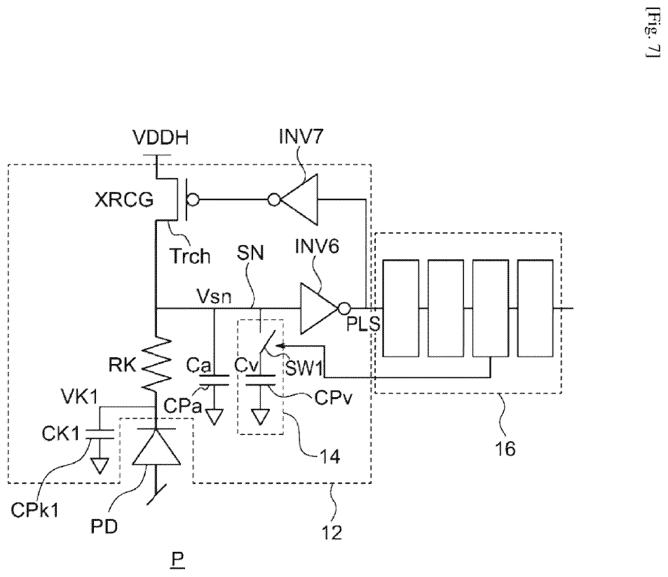

FIG. 7 is a block diagram illustrating an example of the internal configuration of a pixel P according to a second embodiment. In the second embodiment, the sense node SN is connected to the cathode of the photodiode PD via a resistive element RK. The sense node SN is connected to the voltage source VDDH via the transistor Trch. Thereby, the voltage Vsn of the sense node SN is determined by the voltage source VDDH, the resistive element RK, and the like regardless of the voltage source VDDL.

In the second embodiment, the pixel P includes a photodiode PD, a transistor Trch, a resistive element RK, capacitors CPa, CK1, a count rate control circuit 14, a counter circuit 16, and inverters INV6, INV7. The photodiode PD, the capacitor CPa, the count rate control circuit 14, and the counter circuit 16 are the same as those in the first embodiment.

The transistor Trch is connected between the voltage source VDDH and the resistive element RK. The gate of the transistor Trch is connected to the output of the inverter INV7. The transistor Trch is controlled by receiving an inverted signal of the light detection pulse PLS. The transistor Trch is constituted by a p-type MOSFET, for example.

The resistive element RK is connected between the drain of the transistor Trch and the cathode of the photodiode PD.

A capacitor CPk1 is connected between the cathode of the photodiode PD and a reference voltage source (e.g., ground).

The inverter INV6 is connected between the sense node SN and the counter circuit 16. The inverter INV7 is connected between the output of the inverter INV6 and the gate of the transistor Trch.

Next, the operation of the photodetection device according to the second embodiment will be described.

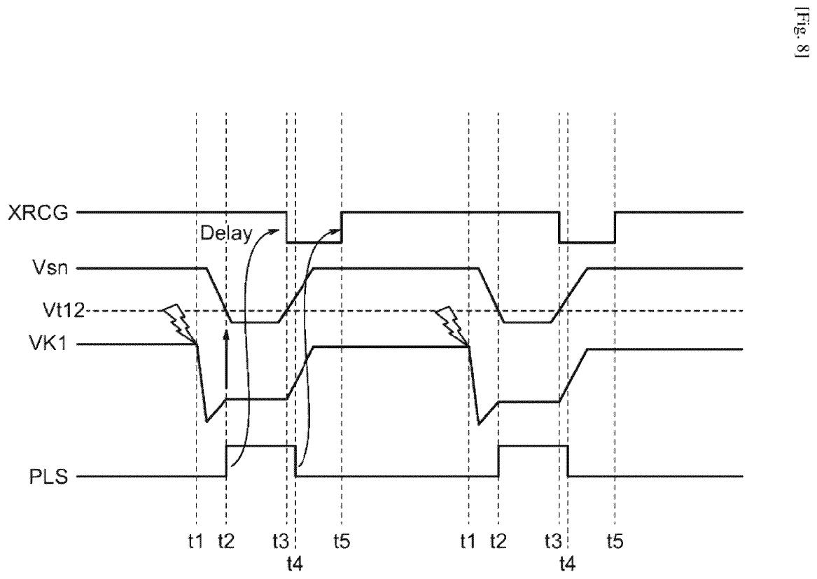

FIG. 8 is a timing diagram illustrating an operation example of the photodetection device according to the second embodiment. In FIG. 8, the switch SW1 is in the non-conductive state, and the capacitance of the sense node SN is Ca, which is relatively small. FIG. 8 illustrates an operation in the low-illuminance mode.

First, the transistor Trch has been in the non-conductive state after the charging of the capacitors CPK1, Ca by the high-level voltage source VDDH. With the light detection pulse PLS being a low-level voltage, the control signal XRCG is set to the high-level voltage. The cathode voltage VK1 and the voltage Vsn of the sense node SN are kept at the high-level voltage. Thereby, a reverse bias voltage is applied to the photodiode PD. In such a state, the photodiode PD waits for entry of a photon.

At t1, when a photon enters the photodiode PD, avalanche breakdown occurs in the photodiode PD, and the cathode voltage VK1 decreases. At this time, the sense node SN is connected to the cathode of the photodiode PD via the resistive element RK. Therefore, in a case where the resistive element RK is sufficiently large, the voltage Vsn decreases with a delay relative to the cathode voltage VK1. After the multiplication of the photodiode PD stops, charges are distributed between the cathode of the photodiode PD and the sense node SN, and the voltage Vsn decreases. At this time, the voltage Vsn is determined by a ratio between the capacitance CK1 of the capacitor CPk1 (the capacitance of the cathode of the photodiode PD) and the capacitance Ca of the capacitor CPa (the capacitance of the sense node SN) as expressed in Expression 7.

Vsn=ΔVK1×(CK1/(CK1+Ca)) (Expression 7)

Note that ΔVK1 is the amount of change in the cathode voltage VK before and after the breakdown of the photodiode PD.

At t2, when the voltage Vsn of the sense node SN falls below a threshold Vt12, the light detection pulse PLS rises by the inverter INV6.

The counter circuit 16 counts the rise of the light detection pulse PLS.

The rise of the light detection pulse PLS is fed back to the gate of the transistor Trch via the inverter INV7. At this time, the rise of the light detection pulse PLS is delayed by the inverter INV7 and fed back to the gate of the transistor Trch. Thereby, at t3, the transistor Trch enters the conductive state, and the cathode voltage VK and the voltage Vsn of the sense node SN are restored to the charged level by the voltage source VDDH. At this time, when the voltage Vsn of the sense node SN exceeds the threshold at t4, the light detection pulse PLS falls.

The fall of the light detection pulse PLS is delayed by the inverter INV7 and fed back to the gate of the transistor Trch as a control signal XRCG. Thereby, at t5, the transistor Trch enters the non-conductive state, and separation is made from the voltage source VDDH with the cathode voltage VK and the voltage Vsn of the sense node SN already restored to the charged level.

Thereafter, the operation from t1 to t5 is repeated every time a photon enters the photodiode PD.

Here, in FIG. 8, the switch SW1 is in the non-conductive state, and the capacitance of the sense node SN is Ca, which is relatively small. Therefore, when avalanche breakdown occurs in the photodiode PD at t2 to t3, the voltages VK1 and Vsn are subjected to capacitance division between the capacitor CPk1 and the capacitor CPa. The voltage Vsn of the sense node SN is determined by a ratio Cs/(Cs+Ca) of the capacitance of the capacitor CPk1 (the capacitance of the photodiode PD) to the capacitance of the capacitor CPa (the capacitance of the sense node SN), and is expressed as Expression 7. In a case where the capacitance Ca is small, the voltage Vsn of the sense node SN changes greatly. When the capacitance Ca of the capacitor CPa is set so that the voltage Vsn of the sense node SN at this time exceeds the threshold Vt12, the light detection pulse PLS is generated at every avalanche breakdown of the photodiode PD. Thus, the counter circuit 16 can perform counting every time one photon enters the photodiode PD. That is, the counter circuit 16 can count the number of photons entering the photodiode PD.

When the count value of photons reaches a predetermined value, a predetermined bit of the counter circuit 16 is inverted. At this time, the counter circuit 16 inverts the control signal of the switch SW1 to bring the switch SW1 into the conductive state.

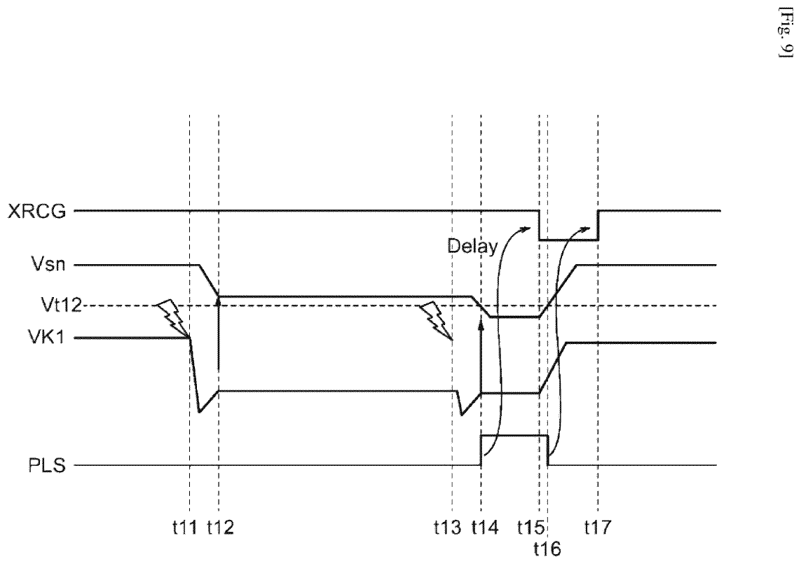

FIG. 9 is a timing diagram illustrating an operation example of the photodetection device when the switch SW1 enters the conductive state. In FIG. 9, the switch SW1 is in the conductive state, and the capacitance of the sense node SN is (Ca+Cv), which is relatively large. FIG. 9 illustrates an operation in the high-illuminance mode.

Before t11, the transistor Trch has entered the non-conductive state after the charging of the capacitors CPK1, Ca, Cv by the high-level voltage source VDDH. Thereby, a reverse bias voltage is applied to the photodiode PD. In such a state, the photodiode PD waits for entry of a photon.

At t11, when a photon enters the photodiode PD, avalanche breakdown occurs in the photodiode PD, and the cathode voltage VK1 decreases.

The decrease in the cathode voltage VK1 is delayed by the resistive element RK and appears at the voltage Vsn of the sense node SN. Therefore, as the cathode voltage VK1 decreases, the voltage Vsn also decreases at t12.

In addition, some of the charges move between the capacitors CPa, CPv and the capacitor CPk1, and the voltage VK1 and the voltage Vsn of the sense node SN become substantially equal. At this time, both the voltages VK1 and Vsn satisfy Expression 8.

VK1=Vsn=ΔVK1×(CK1/(CK1+Ca+Cv)) (Expression 8)

Here, when the switch SW1 is in the conductive state, the capacitance of the sense node SN increases from Ca to (Ca+Cv). Therefore, from t11 to t12, the voltage VK1 is subjected to capacitance division between the capacitor CPk1 and the capacitors CPa, CPv. As a result, the voltage Vsn of the sense node SN is determined by a ratio CK1/(CK1+Ca+Cv) between the capacitance of the capacitor CPk1 (capacitance of the photodiode PD) and the capacitances of the capacitors CPa, CPv (capacitance of the sense node SN), and is expressed as Expression 8. The capacitance (Ca+Cv) is larger than the capacitance Ca, and hence the voltage Vsn of the sense node SN is smaller than that when the switch SW1 is in the non-conductive state. When the capacitances Ca, Cv of the capacitors CPa, CPv are set so that the voltage Vsn of the sense node SN at this time does not fall below the threshold Vt12, the light detection pulse PLS is not generated at the first avalanche breakdown of the photodiode PD. That is, even when one photon enters the photodiode PD, the counter circuit 16 does not perform counting.

Since the light detection pulse PLS is not generated, the transistor Trst remains in the non-conductive state, and the voltage Vsn of the sense node SN is not reset.

When the photon enters the photodiode PD again at t13 after the quenching of the photodiode PD, avalanche breakdown occurs in the photodiode PD, and the cathode voltage VK decreases again as in the operation at t11.

The decrease in the cathode voltage VK1 is delayed by the resistive element RK and appears at the voltage Vsn of the sense node SN. Therefore, as the cathode voltage VK1 decreases, the voltage Vsn also decreases at t14.

In addition, some of the charges move between the capacitors CPa, CPv and the capacitor CPk1, and the voltage VK1 and the voltage Vsn of the sense node SN become substantially equal. At this time, both the voltages VK1 and Vsn satisfy Expression 8.

Between t13 and t14, some of the charges move between the capacitors CPa, CPv and the capacitor CPk1, and the voltage Vsn at the sense node SN and the voltage VK1 at one end of the capacitor CPk1 are averaged and approximately equal. At this time, both the voltages VK1 and Vsn satisfy Expression 9.

VK1=Vsn=ΔVK1×(CK1×(CK1+2Ca+2Cv)/(CK1+Ca+Cv)²) (Expression 9)

Here, the sense node SN has not been reset because the light detection pulse PLS was not generated at the entry of the first photon. Therefore, the voltage Vsn of the sense node SN remains at a charged level of ΔVK1×(CK1/(CK1+Ca+Cv)). Furthermore, at the entry of the second photon, the sense node SN is further charged, and the voltage Vsn of the sense node SN becomes ΔVK1×(CK1×(CK1+2Ca+2Cv)/(CK1+Ca+Cv)²). When the capacitances Ca, Cv of the capacitors CPa, CPv are set so that the voltage Vsn of the sense node SN at this time falls below the threshold Vt12, the light detection pulse PLS is generated every time avalanche breakdown occurs in the photodiode PD twice. Thus, the counter circuit 16 can count 1 every time two photons enter the photodiode PD.

At t14, when the light detection pulse PLS rises, the counter circuit 16 increases the count by 1, and the light detection pulse PLS is fed back to the gate of the transistor Trch. Thereby, at t15, the transistor Trch enters the conductive state, and the voltage VK1 and the voltage Vsn are restored to the charged level by the voltage source VDDH.

At t16, when the voltage Vsn of the sense node SN exceeds the threshold Vt12, the light detection pulse PLS falls. At t17, the transistor Trch returns to the non-conductive state. Thereby, separation is made from the voltage source VDDH with the cathode voltage VK and the voltage Vsn of the sense node SN already restored to the charged level.

Thereafter, the operation from the operation from t11 to t17 is repeated every time two photons enter the photodiode PD.

As described above, according to the second embodiment, the capacitance of the sense node SN is controlled while the photodiode PD detects all entering photons, whereby it is possible to limit the generation frequency of the light detection pulse PLS and reduce the count value of the counter circuit 16. Therefore, the second embodiment can obtain the effects similar to those of the first embodiment.

Also, in the second embodiment, similarly to the first embodiment, by changing the capacitance Cv of the capacitor CPv, the counter circuit 16 can increase the count value by 1 every time the photodiode PD breaks down n times (every time n photons are detected). As a result, the count value of the counter circuit 16 can be reduced.

### Third Embodiment

FIG. 10 is a block diagram illustrating an example of an internal configuration of a pixel P according to a third embodiment. In the third embodiment, instead of the resistive element RK, a transistor Tclip is connected between the source of the transistor Trch and the cathode of the photodiode PD. The transistor Tclip is controlled to the conductive state or the non-conductive state by a control signal CLIP from the vertical selection circuit 30. The transistor Tclip is constituted by a p-type MOSFET, for example.

In the second embodiment, the resistive element RK determines the generation timing of the light detection pulse PLS, but in the third embodiment, the control signal CLIP determines the generation timing of the light detection pulse PLS. The control signal CLIP may periodically repeat high and low. Other configurations of the third embodiment may be similar to those of the second embodiment.

Next, the operation of the photodetection device according to the third embodiment will be described.

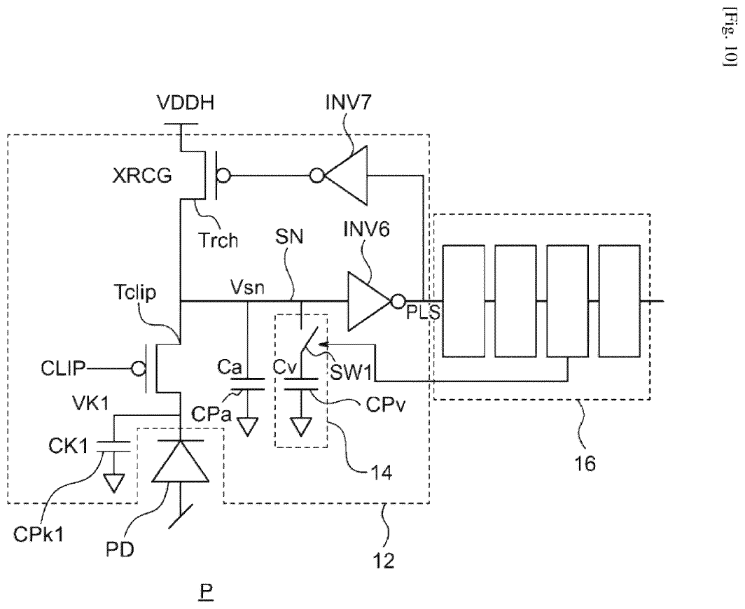

FIG. 11 is a timing diagram illustrating an operation example of the photodetection device according to the third embodiment. In FIG. 11, the switch SW1 is in the non-conductive state, and the capacitance of the sense node SN is Ca, which is relatively small. FIG. 11 illustrates an operation in the low-illuminance mode.

The operation up to t1 is similar to that in the second embodiment. In such a state, the photodiode PD waits for entry of a photon. Note that the transistor Tclip is in the non-conductive state with a reverse bias voltage applied to the photodiode PD.

At t1, when a photon enters the photodiode PD, avalanche breakdown occurs in the photodiode PD, and the cathode voltage VK1 decreases. At this time, with the transistor Tclip in the non-conductive state, the voltage Vsn of the sense node SN does not decrease.

At t2, when the signal CLIP falls, the transistor Tclip enters the conductive state. As a result, the voltage Vsn of the sense node SN is connected to the cathode voltage VK1 and decreases.

At t3, when the voltage Vsn of the sense node SN falls below the threshold Vt12, the light detection pulse PLS rises by the inverter INV6.

In this manner, the fall timing of the voltage Vsn and the rise timing of the light detection pulse PLS can be controlled by the fall timing of the signal CLIP. The charges of the capacitor CPk1 are distributed between the cathode of the photodiode PD and the sense node SN, the voltage Vsn decreases, and the voltage VK1 increases. At this time, the voltage Vsn is determined by a ratio between the capacitance CK1 of the capacitor CPk1 (the capacitance of the cathode of the photodiode PD) and the capacitance Ca of the capacitor CPa (the capacitance of the sense node SN) as expressed in Expression 7.

The counter circuit 16 counts the rise of the light detection pulse PLS.

The rise of the light detection pulse PLS is delayed and fed back to the gate of the transistor Trch via the inverter INV7. Thereby, at t4, the transistor Trch enters the conductive state, and the cathode voltage VK and the voltage Vsn of the sense node SN are restored to the charged level by the voltage source VDDH. At t5, when the voltage Vsn of the sense node SN exceeds the threshold Vt12, the light detection pulse PLS falls. The fall of the light detection pulse PLS is delayed by the inverter INV7 and fed back to the gate of the transistor Trch. As a result, at t6, the transistor Trch returns to the non-conductive state, and separation is made from the voltage source VDDH with the cathode voltage VK and the voltage Vsn of the sense node SN already restored to the charged level.

After the restoration of the cathode voltage VK at the charged level and the recharging of the sense node SN, at t7, the control signal CLIP rises and the transistor Tclip enters the non-conductive state. As a result, the state returns to the state before t1.

Thereafter, the operation from the operation from t1 to t7 is repeated every time a photon enters the photodiode PD. The control signal CLIP may periodically repeat high and low.

In the third embodiment, the control signal CLIP determines the generation timing of the light detection pulse PLS. Other operations of the third embodiment may be similar to the operations of the second embodiment. Thus, the counter circuit 16 can perform counting every time one photon enters the photodiode PD.

When the number of counts of photons reaches a predetermined value, a predetermined bit of the counter circuit 16 is inverted. At this time, the counter circuit 16 inverts the control signal to bring the switch SW1 into the conductive state.

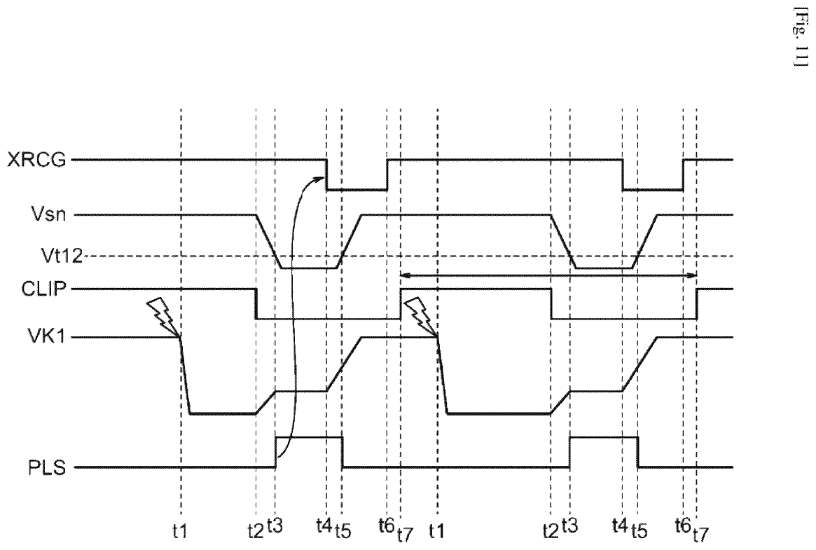

FIG. 12 is a timing diagram illustrating an operation example of the photodetection device when the switch SW1 enters the conductive state. In FIG. 12, the switch SW1 is in the conductive state, and the capacitance of the sense node SN is (Ca+Cv), which is relatively large. FIG. 12 illustrates an operation in the high-illuminance mode.

The operation until t11 is similar to that in the second embodiment. In such a state, the photodiode PD waits for entry of a photon. Note that the transistor Tclip is in the non-conductive state with a reverse bias voltage applied to the photodiode PD.

At t11, when a photon enters the photodiode PD, avalanche breakdown occurs in the photodiode PD, and the cathode voltage VK1 decreases. At this time, with the transistor Tclip in the non-conductive state, the voltage Vsn of the sense node SN does not decrease.

At t12, when the signal CLIP falls, the transistor Tclip enters the conductive state. As a result, the voltage Vsn of the sense node SN is connected to the cathode voltage VK1 and decreases. At t13, some of the charges accumulated in the capacitor CPk1 move to the capacitors CPa, CPv, and the voltage VK1 and the voltage Vsn of the sense node SN become substantially equal. At this time, both the voltages VK1 and Vsn satisfy Expression 8.

Here, with the switch SW1 in the conductive state, as in the second embodiment, when the capacitances Ca, Cv of the capacitors CPa, CPv are set so that the voltage Vsn of the sense node SN at this time does not fall below the threshold Vt12, the light detection pulse PLS is not generated at the first avalanche breakdown of the photodiode PD. That is, even when one photon enters the photodiode PD, the counter circuit 16 does not perform counting.

Since the light detection pulse PLS is not generated, the transistor Trch remains in the non-conductive state, and the voltage CK1 of the capacitor CPk1 and the voltage Vsn of the sense node SN are not reset.

Next, at t14, the control signal CLIP is raised to bring the transistor Tclip into the non-conductive state.

Next, when the second photon enters the photodiode PD at t15, avalanche breakdown occurs in the photodiode PD, and the cathode voltage VK1 decreases again as in the operation at t11.

At t16, when the signal CLIP falls, the transistor Tclip enters the conductive state. As a result, the voltage Vsn of the sense node SN is connected to the cathode voltage VK1 and decreases. Some of the charges accumulated in the capacitor CPk1 move to the capacitors CPa, CPv, and the voltage VK1 and the voltage Vsn of the sense node SN become substantially equal. At this time, both the voltages VK1 and Vsn satisfy Expression 9.

Here, the sense node SN has not been reset because the light detection pulse PLS was not generated at the entry of the first photon. Therefore, the voltage Vsn of the sense node SN remains at a charged level of ΔVK1×(CK1/(CK1+Ca+Cv)). Furthermore, at the entry of the second photon, the sense node SN is further charged, and the voltage Vsn of the sense node SN becomes ΔVK1×(CK1×(CK1+2Ca+2Cv)/(CK1+Ca+Cv)²). When the capacitances Ca, Cv of the capacitors CPa, CPv are set so that the voltage Vsn of the sense node SN at this time falls below the threshold Vt12, the light detection pulse PLS is generated every time avalanche breakdown occurs in the photodiode PD twice. Thus, the counter circuit 16 can count 1 every time two photons enter the photodiode PD.

At t17, when the light detection pulse PLS rises, the counter circuit 16 increases the count by 1, and the light detection pulse PLS is fed back to the gate of the transistor Trch. Thereby, at t18, the signal XRCG falls to bring the transistor Trch into the conductive state, and the voltage VK1 and the voltage Vsn are restored to the charged level by the voltage source VDDH. When the voltage Vsn of the sense node SN is restored to the charged level by the voltage source VDDH, the light detection pulse PLS falls at t19, and the signal XRCG rises and the transistor Trch returns to the non-conductive state at t20.

Thereafter, the operation from t11 to t21 is repeated every time two photons enter the photodiode PD.

As described above, according to the third embodiment, the capacitance of the sense node SN is controlled while the photodiode PD detects all entering photons, whereby it is possible to limit the generation frequency of the light detection pulse PLS and reduce the count value of the counter circuit 16. Therefore, the third embodiment can obtain the effects similar to those of the second embodiment.

Also, in the third embodiment, similarly to the second embodiment, by changing the capacitance Cv of the capacitor CPv, the counter circuit 16 can increase the count value by 1 every time the photodiode PD breaks down n times (every time n photons are detected). This can further reduce the count value of the counter circuit 16.

In the third embodiment, the transistor Tclip is used instead of the resistive element RK. Therefore, by decreasing the on-resistance of the transistor Tclip, the recharge time of the capacitors CPk1, Ca, Cv can be shortened.

### Fourth Embodiment

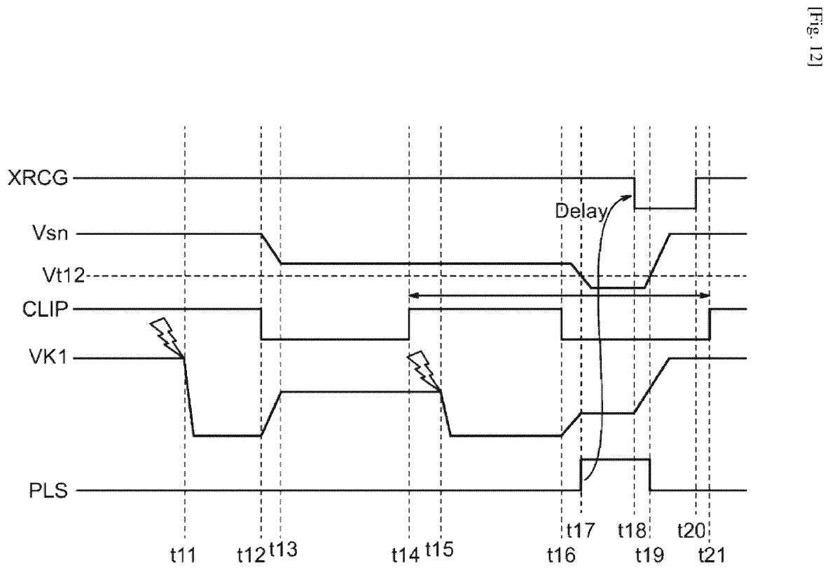

FIG. 13 is a block diagram illustrating an example of an internal configuration of a pixel P according to a fourth embodiment. In the fourth embodiment, the plurality of photodiodes PD1, PD2, the plurality of capacitors CPk1, CPk2, and the plurality of transistors Tclip1, Tclip2 are connected in parallel between the common sense node SN and the reference voltage source. As for the photodiode PD2 and the transistor Tclip2, the configurations of each of the plurality of photodiodes PD1, PD2, each of the plurality of capacitors CPk1, CPk2, and each of the plurality of transistors Tclip1, Tclip2 may be the same as the configurations of the photodiode PD, the capacitor CPk1, and the transistor Tclip of the third embodiment, respectively. As a result, in the fourth embodiment, one counter circuit 16 counts photons entering the plurality of photodiodes PD1, PD2. Other configurations of the fourth embodiment may be similar to those of the third embodiment.

Next, the operation of the photodetection device according to the fourth embodiment will be described.

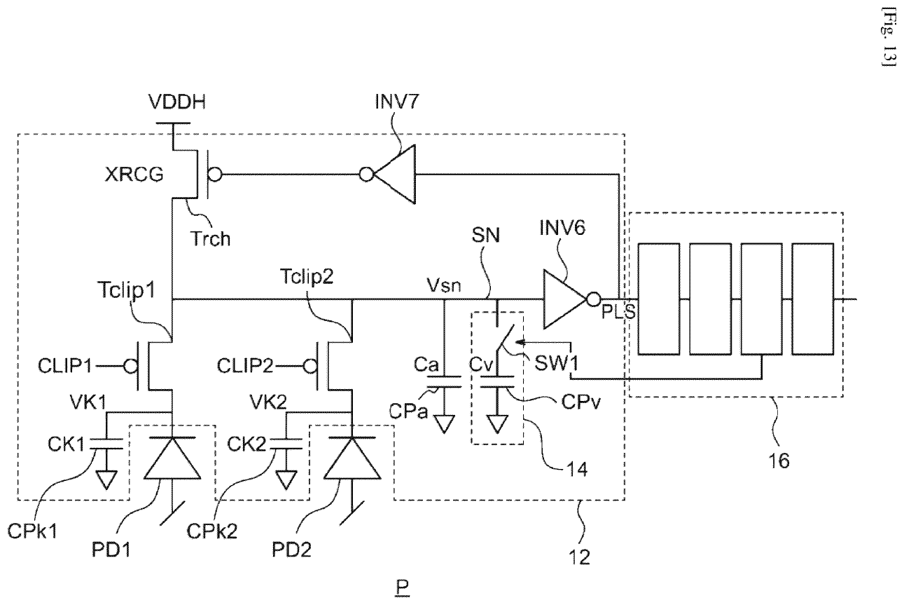

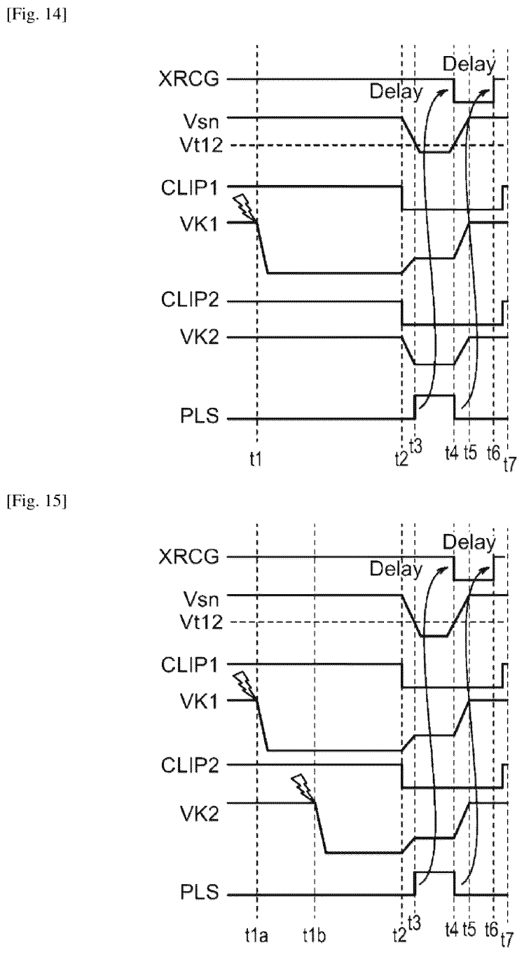

FIGS. 14 and 15 are timing diagrams illustrating an operation example of the photodetection device according to the fourth embodiment. In FIGS. 14 and 15, the switch SW1 is in the non-conductive state, and the capacitance of the sense node SN is Ca, which is relatively small. FIGS. 14 and 15 illustrate the operation in the low-illuminance mode. FIG. 14 illustrates an operation when one photodiode PD1 is detecting a photon. FIG. 15 illustrates an operation when both the photodiodes PD1, PD2 are detecting photons.

The operation from t1 to t1a in each of FIGS. 14 and 15 is basically similar to that in the second embodiment. At this time, the capacitors CPk1, CPk2, Ca are in the charged state. In such a state, the photodiodes PD1, PD2 wait for entry of photons. Note that the transistors Tclip1, Tclip2 are in the non-conductive state with a reverse bias voltage applied to each of the photodiodes PD1, PD2.

### Entry of Photon into Only PD1

As illustrated in FIG. 14, when a photon enters the photodiode PD1 at t1, avalanche breakdown occurs in the photodiode PD1, and the cathode voltage VK1 decreases. At this time, with the transistor Tclip1 in the non-conductive state, the voltage Vsn of the sense node SN does not decrease. In addition, since no photon enters the photodiode PD2, the cathode voltage VK2 of the photodiode PD2 does not decrease.

At t2, when the control signals CLIP1, CLIP2 fall, the transistors Tclip1, Tclip2 enter the conductive state. As a result, the voltage Vsn of the sense node SN is connected to the cathode voltage VK1 and decreases.

At t3, when the voltage Vsn of the sense node SN falls below the threshold Vt12, the light detection pulse PLS rises by the inverter INV6.

In this manner, the fall timing of the voltage Vsn and the rise timing of the light detection pulse PLS can be controlled by the fall timing of the control signals CLIP1, CLIP2. The charges of the capacitor CPk1 are distributed between the cathode of the photodiode PD1 and the sense node SN, the voltage Vsn decreases, and the voltage VK1 increases. At this time, the voltages Vsn, VK1, VK2 are substantially equal. The voltage Vsn is determined by a ratio (CK1/(CK1+CK2+Ca)) between the capacitances CK1 and CK2 (Capacitance of cathodes of photodiodes PD1, PD2) of the capacitors CPK1, CPk2 and the capacitance Ca (capacitance of the sense node SN) of the capacitor CPa.

The counter circuit 16 counts the rise of the light detection pulse PLS.

The subsequent recharging operation from t4 to t7 may be the same as that in the third embodiment.

After the capacitors CPk1, CPk2 and the sense node SN are restored to the charged level, at t7, the control signals CLIP1, CLIP2 rise, and the transistors Tclip1, Tclip2 enter the non-conductive state. As a result, the state returns to the state before t1. The control signals CLIP1, CLIP2 are synchronized and periodically repeat high and low.

Note that the operation of the photodetection device 100 in a case where photons enter only the photodiode PD2 can be easily understood with reference to FIG. 14, and hence the description thereof will be omitted.

### Entry of Photons into Both PD1 and PD2

As illustrated in FIG. 15, when photons enter both the photodiodes PD1, PD2 at t1a and t1b, avalanche breakdown occurs in the photodiodes PD1, PD2, and both the cathode voltages VK1, VK2 decrease. At this time, with the transistors Tclip1, Tclip2 in the non-conductive state, the voltage Vsn of the sense node SN does not decrease.

At t2, when the control signals CLIP1, CLIP2 fall, the transistors Tclip1, Tclip2 enter the conductive state. As a result, the sense node SN is connected to the capacitors CPk1, CPk2, and the voltage Vsn decreases due to the cathode voltages VK1, VK2.

At t3, when the voltage Vsn of the sense node SN falls below the threshold Vt12, the light detection pulse PLS rises by the inverter INV6.

In this manner, the fall timing of the voltage Vsn and the rise timing of the light detection pulse PLS can be controlled by the fall timing of the control signals CLIP1, CLIP2. The charges of the capacitors CPK1, CPk2 are distributed to the sense node SN, the voltage Vsn decreases, and the voltages VK1, VK2 increase. At this time, the voltages Vsn, VK1, VK2 are substantially equal. The voltage Vsn is determined by a ratio (CK1+CK2/(CK1+CK2+Ca)) between the capacitances CK1 and CK2 (Capacitance of cathodes of photodiodes PD1, PD2) of the capacitors CPk1, CPk2 and the capacitance Ca (capacitance of the sense node SN) of the capacitor CPa.

The counter circuit 16 counts the rise of the light detection pulse PLS.

The subsequent recharging operation from t4 to t7 may be the same as that in the third embodiment.

After the capacitors CPK1, CPk2 and the sense node SN are restored to the charged level, at t7, the control signals CLIP1, CLIP2 rise, and the transistors Tclip1, Tclip2 enter the non-conductive state. As a result, the state returns to the state before t1. The control signals CLIP1, CLIP2 are synchronized and periodically repeat high and low.

As described above, in the low-illuminance mode, in a case where at least one of the two photodiodes PD1, PD2 detects a photon, the light detection pulse PLS is generated, and the counter circuit 16 counts the light detection pulse PLS.

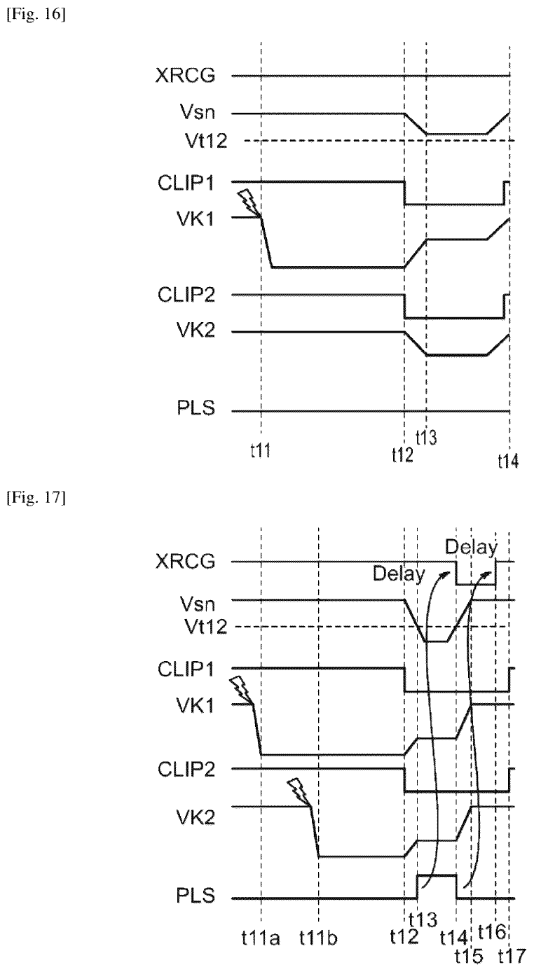

FIGS. 16 and 17 are timing diagrams illustrating an operation example of the photodetection device according to the fourth embodiment. In FIGS. 16 and 17, the switch SW1 is in a conductive state, and the capacitance of the sense node SN is (Ca+Cv), which is relatively large. FIGS. 16 and 17 illustrate operations in the high-illuminance mode. FIG. 16 illustrates an operation when one photodiode PD1 is detecting a photon. FIG. 17 illustrates an operation when both the photodiodes PD1, PD2 are detecting photons.

The operation from t11 to t11a in each of FIGS. 16 and 17 is basically similar to that in the second embodiment. At this time, the capacitors CPk1, CPk2, Ca are in the charged state. In such a state, the photodiodes PD1, PD2 wait for entry of photons. Note that the transistors Tclip1, Tclip2 are in the non-conductive state with a reverse bias voltage applied to each of the photodiodes PD1, PD2.

### Entry of Photon into Only PD1

As illustrated in FIG. 16, when a photon enters the photodiode PD1 at t11, avalanche breakdown occurs in the photodiode PD1, and the cathode voltage VK1 decreases. At this time, with the transistor Tclip1 in the non-conductive state, the voltage Vsn of the sense node SN does not decrease. In addition, since no photon enters the photodiode PD2, the cathode voltage VK2 of the photodiode PD2 does not decrease.

At t12, when the control signals CLIP1, CLIP2 fall, the transistors Tclip1, Tclip2 enter the conductive state. As a result, the voltage Vsn of the sense node SN is connected to the cathode voltage VK1 and decreases. At t13, some of the charges accumulated in the capacitor CPk1 move to the capacitors CPa, CPv, CPk2, and the voltages VK1, VK2 and the voltage Vsn of the sense node SN become substantially equal.

Here, with the switch SW1 in the conductive state, as in the second embodiment, when the capacitances Ca, Cv of the capacitors CPa, CPv are set so that the voltage Vsn of the sense node SN at this time does not fall below the threshold Vt12, the light detection pulse PLS is not generated at the first avalanche breakdown of the photodiode PD. That is, even when one photon enters the photodiode PD, the counter circuit 16 does not perform counting.

Since the light detection pulse PLS is not generated, the transistor Trch remains in the non-conductive state, and the voltage CK1 of the capacitor CPk1 and the voltage Vsn of the sense node SN are not reset.

Next, at t14, the control signal CLIP is raised to bring the transistor Tclip into the non-conductive state. As a result, the photodetection device 100 returns to the state before t11. The control signals CLIP1, CLIP2 are synchronized and periodically repeat high and low.

### Entry of Photons into Both PD1 and PD2

As illustrated in FIG. 17, when photons enter both the photodiodes PD1, PD2 at t11a and t11b, avalanche breakdown occurs in the photodiodes PD1, PD2, and both the cathode voltages VK1, VK2 decrease. At this time, with the transistors Tclip1, Tclip2 in the non-conductive state, the voltage Vsn of the sense node SN does not decrease.

At t12, when the control signals CLIP1, CLIP2 fall, the transistors Tclip1, Tclip2 enter the conductive state. As a result, the sense node SN is connected to the capacitors CPk1, CPk2, and the voltage Vsn decreases due to the cathode voltages VK1, VK2.

At t13, when the voltage Vsn of the sense node SN falls below the threshold Vt12, the light detection pulse PLS rises by the inverter INV6.

In this manner, the fall timing of the voltage Vsn and the rise timing of the light detection pulse PLS can be controlled by the fall timing of the control signals CLIP1, CLIP2. The charges of the capacitors CPK1, CPk2 are distributed to the sense node SN, the voltage Vsn decreases, and the voltages VK1, VK2 increase. At this time, the voltages Vsn, VK1, VK2 are substantially equal. The voltage Vsn is determined by a ratio (CK1+CK2/(CK1+CK2+Ca)) between the capacitances CK1 and CK2 (Capacitance of cathodes of photodiodes PD1, PD2) of the capacitors CPk1, CPk2 and the capacitance Ca (capacitance of the sense node SN) of the capacitor CPa.

The counter circuit 16 counts the rise of the light detection pulse PLS.

The subsequent recharging operation from t14 to t17 may be the same as the operation from t4 to t7 in FIG. 15 After the capacitors CPk1, CPk2 and the sense node SN are restored to the charged level, at t17, the control signals CLIP1, CLIP2 rise, and the transistors Tclip1, Tclip2 enter the non-conductive state. As a result, the state returns to the state before t11. The control signals CLIP1, CLIP2 are synchronized and periodically repeat high and low.

As described above, in the high-illuminance mode, even when only one of the two photodiodes PD1, PD2 detects a photon, the light detection pulse PLS is not generated, and the counter circuit 16 does not increase the count value. On the other hand, when both of the two photodiodes PD1, PD2 detect photons, the light detection pulse PLS is generated, and the counter circuit 16 counts the light detection pulse PLS.

As described above, in the fourth embodiment, when both of the two photodiodes PD1, PD2 detect photons, the counter circuit 16 increases the count value by 1, so that the count value of the counter circuit 16 can be reduced. That is, when the photodiodes PD1, PD2 detect two photons in total, the counter circuit 16 increases the count value by 1. Therefore, the fourth embodiment can obtain the effects similar to those of the third embodiment.

Assuming that the number of photodiodes PD connected in parallel to one counter circuit 16 (one sense node SN) is n, the counter circuit 16 can increase the count value by 1 every time the n photodiodes PD break down (every time n photons are detected) in the high-illuminance mode. This can further reduce the count value of the counter circuit 16.

In order for the counter circuit 16 to count 1 for the detection of one photon using any one of the two photodiodes PD1, PD2, Ca, Ck1, Ck2 are set so as to satisfy Expressions 10 and 11. In order for the counter circuit 16 to count 1 when both of the two photodiodes PD1, PD2 each detect one photon, Ca, Ck1, Ck2 are set so as to satisfy Expressions 12 to 14. Note that Vth is the threshold voltage of the inverter INV6. ΔVK1 is the amount of change in the cathode voltage VK1 before and after the breakdown of the photodiode PD1. ΔVK2 is the amount of change in the cathode voltage VK2 before and after the breakdown of the photodiode PD2.

Ca<Ck1 (ΔVk1−Vth)/Vth (Expression 10)

Ca<Ck2 (ΔVk2−Vth)/Vth (Expression 11)

Ca+Cv>Ck1 (ΔVk1−Vth)/Vth (Expression 12)

Ca+Cv>Ck2 (ΔVk2−Vth)/Vth (Expression 13)

Ca+Cv<Ck1 (ΔVk1−Vth)/Vth+Ck2 (ΔVk2−Vth)/Vth (Expression 14)

Other configurations of the fourth embodiment may be similar to those of the third embodiment. Therefore, the fourth embodiment can obtain the effects similar to those of the third embodiment.

### Fifth Embodiment

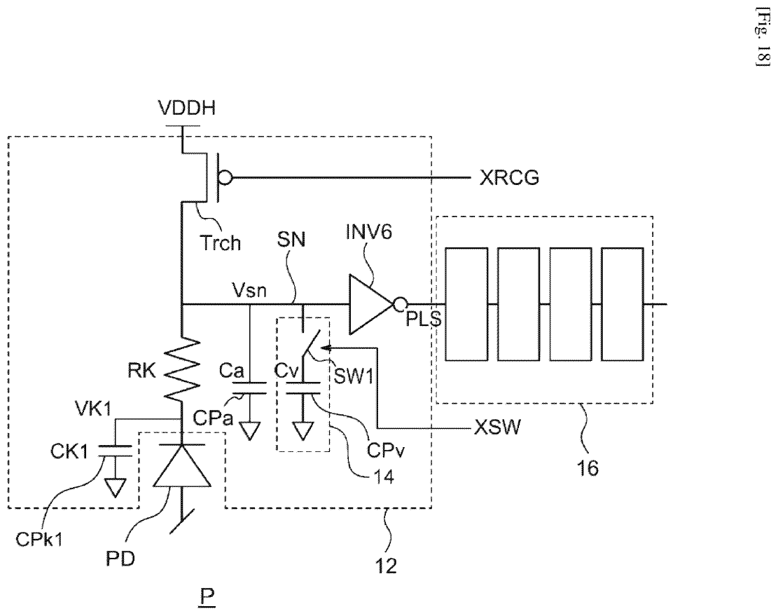

FIG. 18 is a block diagram illustrating an example of an internal configuration of the pixel P according to a fifth embodiment. In the fifth embodiment, the transistor Trch and the switch SW1 are controlled by the vertical selection circuit 30 or the control circuit 70 outside the pixel P. Therefore, the switching between the low-illuminance mode and the high-illuminance mode and the charging timing of the capacitors CPK1, Ca (and Cv) are controlled by the control signals XRCG, XSW from the outside. Other configurations of the fifth embodiment may be similar to those of the second embodiment.

In the fifth embodiment, any setting can be made for the charging timing of the capacitors CPK1, Ca (and Cv) can be set arbitrarily regardless of the light detection pulse PLS. That is, the charge cycle of the capacitors CPK1, Ca (and Cv) can be set arbitrarily. The photodetection device 100 can detect the entry of a predetermined number n of photons into the photodiode PD during the arbitrarily set charge cycle of the capacitors CPK1, Ca.

For example, in the low-illuminance mode, the above charge cycle is set longer to enhance sensitivity, and in the high-illuminance mode, the above charge cycle is set shorter to prevent saturation. Furthermore, when a predetermined number n of photons enter the photodiode PD, the counter circuit 16 can increase the count value by 1. This enables the photodetection device 100 to widen the dynamic range and improve the SNR while preventing an increase in the count value. Other operations of the fifth embodiment may be similar to those of the second embodiment.

FIG. 19 is a timing diagram illustrating an operation example of the photodetection device according to the fifth embodiment. In FIG. 19, the switch SW1 is in the non-conductive state, and the capacitance of the sense node SN is Ca, which is relatively small. FIG. 19 illustrates an operation in the low-illuminance mode.

In the fifth embodiment, the vertical selection circuit 30 lowers the control signal XRCG in the cycle CLK, and charges the capacitors CPK1, Ca in the cycle CLK via the transistor Trch.

When a photon enters the photodiode PD at t1 between the charging of the capacitors CPk1, Ca and the next charging, avalanche breakdown occurs in the photodiode PD, and the cathode voltage VK1 and the voltage Vsn of the sense node SN decrease. At this time, the operation of the pixels P from t1 to t5 may be the same as that in the second embodiment. However, the light detection pulse PLS is not fed back to the gate of the transistor Trch.

As a result, when one photon enters the photodiode PD within the period of the cycle CLK, the counter circuit 16 increases the count value by 1. That is, the counter circuit 16 can detect a photon entering the photodiode PD in each cycle CLK.

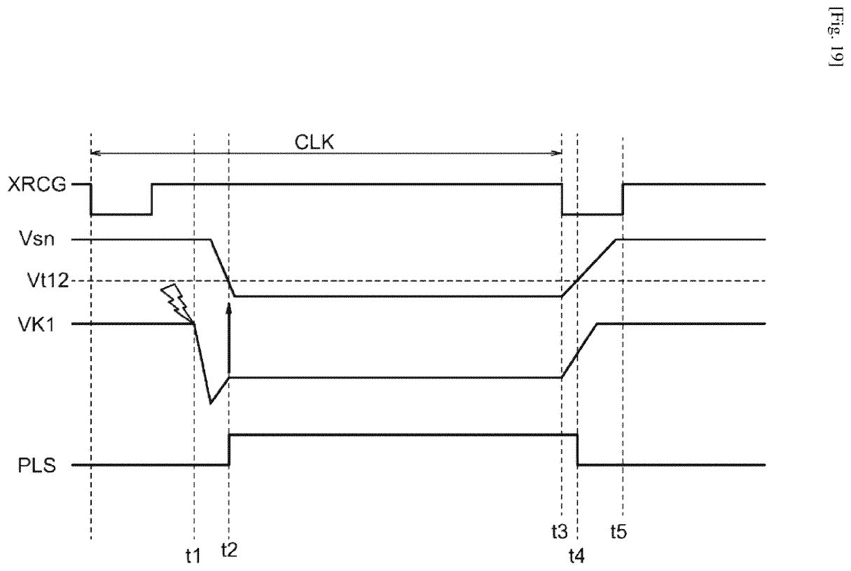

FIG. 20 is a timing diagram illustrating an operation example of the photodetection device according to the fifth embodiment. In FIG. 20, the switch SW1 is in the conductive state, and the capacitance of the sense node SN is (Ca+Cv), which is relatively large. FIG. 20 illustrates a case where one photon enters the photodiode PD in the operation in the high-illuminance mode.

The operation of the pixel P from t11 to t12 may be the same as that in the second embodiment. At t11, when a photon enters the photodiode PD, avalanche breakdown occurs in the photodiode PD, and the cathode voltage VK1 decreases. However, the voltage Vsn of the sense node SN does not fall below the threshold Vt12, and hence the light detection pulse PLS is not generated. Thus, even when one photon enters the photodiode PD, the counter circuit 16 does not perform counting.

In a case where the second photon does not enter, at t15 to t17, the control signal XRCG falls in the next charging operation, and the capacitors CPk1, Ca are restored to the charged level via the transistor Trch. As a result, the state is reset to the state of t11.

In the high-illuminance mode, in a case where two photons enter during the period of the cycle CLK, the operation in the fifth embodiment may be the same as the operation in the second embodiment illustrated in FIG. 9. Therefore, the fifth embodiment can obtain the effects similar to those of the second embodiment. Further, In the fifth embodiment, the sensitivity can be enhanced by setting the charge cycle CLK longer in the low-illuminance mode, and the saturation can be prevented by setting the charge cycle CLK shorter in the high-illuminance mode. This enables the photodetection device 100 to widen the dynamic range and improve the SNR while preventing an increase in the count value.

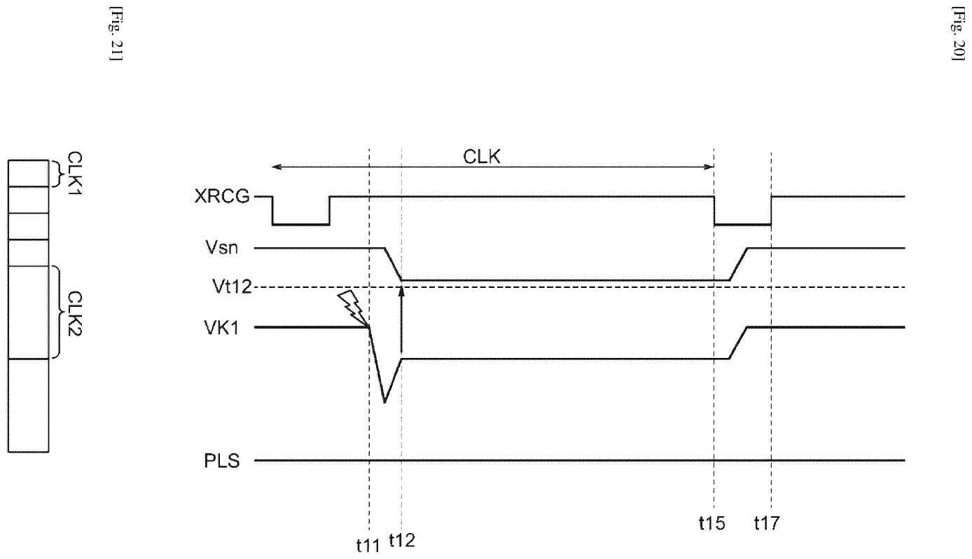

FIG. 21 is a conceptual diagram illustrating charge cycles CLK1, CLK2 in the fifth embodiment. In the fifth embodiment, a plurality of charge cycles CLK1, CLK2 may be included in one exposure period of the photodiode PD. For example, the charge cycle CLK1 is shorter than the charge cycle CLK2 and is suitable for the high-illuminance mode in which the count value is increased when a plurality of photons is detected. On the other hand, the charge cycle CLK2 is longer than the charge cycle CLK1 and is suitable for the low-illuminance mode in which the count value is increased when one photon is detected. This enables the photodetection device 100 to widen the dynamic range and improve the SNR while preventing an increase in the count value.

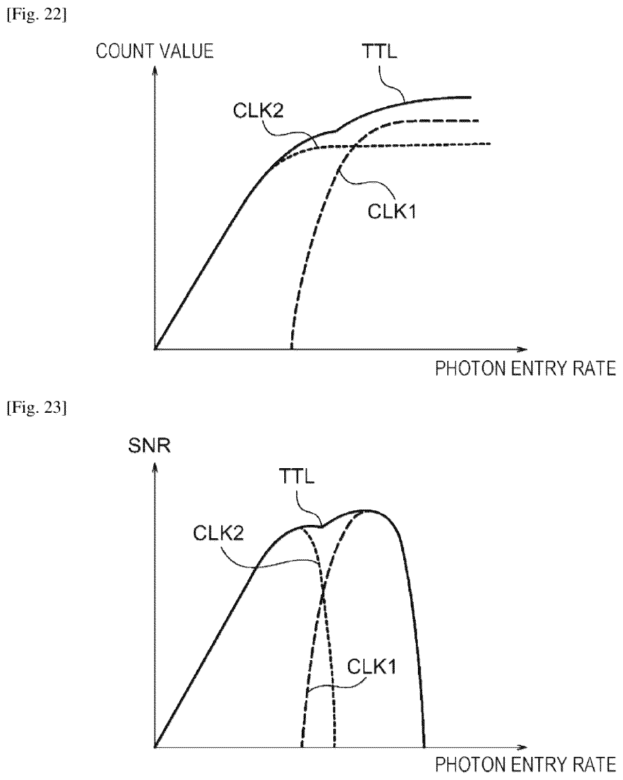

FIG. 22 is a graph illustrating a relationship between a photon entry rate and the count value. The charge cycle CLK1 is used in the high-illuminance mode, and increases the count value when a plurality of photons is detected. Further, In the high-illuminance mode, the switch SW1 is in the conductive state. The charge cycle CLK2 is used in the low-illuminance mode, and increases the count value when one photon is detected. Further, in the low-illuminance mode, the switch SW1 is in the conductive state. Therefore, the charge cycle CLK2 is used when the photon entry rate is small, and the charge cycle CLK1 is used when the photon entry rate increases.

A total count value TTL is the sum of the count value of the charge cycle CLK1 and the count value of the charge cycle CLK2.

In the low-illuminance mode, with the charge cycle CLK2 applied and the switch SW1 in the non-conductive state, the counter circuit 16 increases the count value for each photon. Therefore, the SNR in the low-illuminance mode can be increased. On the other hand, in the high-illuminance mode, with the charge cycle CLK1 applied and the switch SW1 in the conductive state, the counter circuit 16 increases the count value for each of the plurality of photons. Therefore, the total count value TTL can be kept low. This prevents the saturation of the count value in the high-illuminance mode to lead to an increase in the dynamic range.

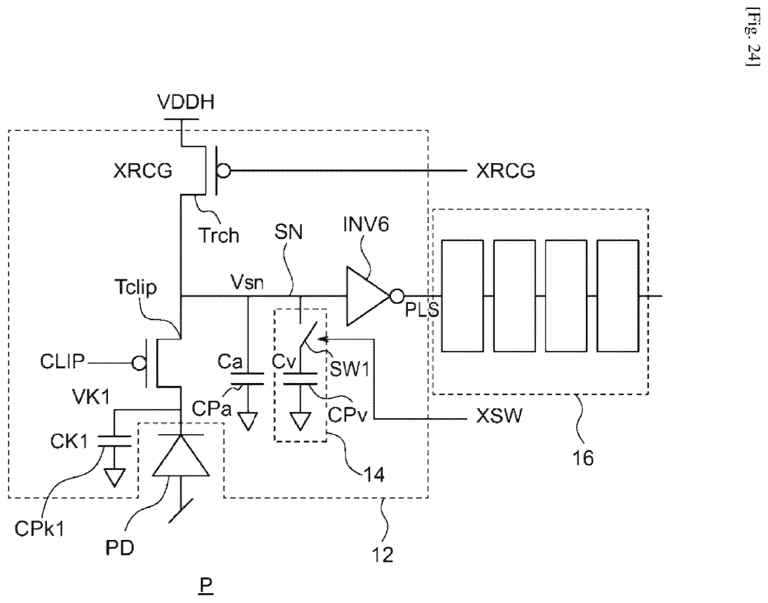

FIG. 23 is a graph illustrating a relationship between the photon entry rate and the SNR. Note that the SNR is proportional to N/N^{1/2}. N is the number of photons detected by the photodiode PD.

In the low-illuminance mode, the counter circuit 16 increases the count value for each photon. In the high-illuminance mode, the counter circuit 16 increases the count value for each of the plurality of photons. Hence the counter circuit 16 can accurately count many photons by increasing the count value for each of the plurality of photons. Therefore, the SNR can be kept high even in the high-illuminance mode.

### Sixth Embodiment

FIG. 24 is a block diagram illustrating an example of the internal configuration of a pixel P according to a sixth embodiment. In the sixth embodiment, the transistor Trch and the switch SW1 are controlled by the vertical selection circuit 30 or the control circuit 70 outside the pixel P. Therefore, the switching between the low-illuminance mode and the high-illuminance mode and the charging timing of the capacitors CPk1, Ca (and Cv) are controlled by the control signals XRCG, XSW from the outside of the counter circuit 16 and the count rate control circuit 14. Other configurations of the sixth embodiment may be similar to those of the third embodiment. That is, the sixth embodiment is a combination of the third embodiment and the fifth embodiment. Therefore, the sixth embodiment can obtain the effects similar to those of the third and fifth embodiments.

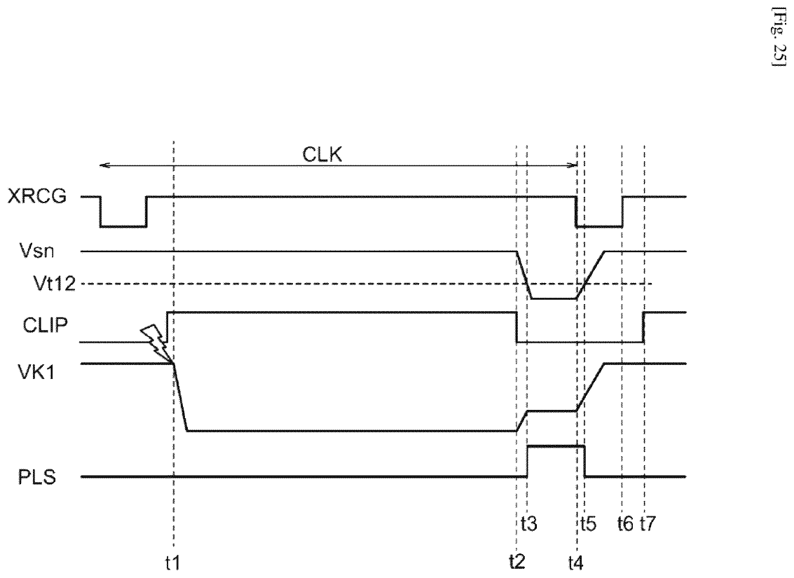

FIG. 25 is a timing diagram illustrating an operation example of the photodetection device according to the sixth embodiment. In FIG. 25, the switch SW1 is in the non-conductive state, and the capacitance of the sense node SN is Ca, which is relatively small. FIG. 25 illustrates an operation in the low-illuminance mode.

In the sixth embodiment, the vertical selection circuit 30 lowers the control signal XRCG in the cycle CLK to charge the capacitors CPk1, Ca via the transistor Trch.

When a photon enters the photodiode PD at t1 between the charging of the capacitors CPk1, Ca and the next charging, avalanche breakdown occurs in the photodiode PD, and the cathode voltage VK1 decreases. At this time, since the control signal CLIP has risen, the transistor Tclip is in the non-conductive state, and the voltage Vsn of the sense node SN has been kept at the charged level.

After the signal CLIP falls, the operation of the pixel P from t2 to t7 may be the same as that in the third embodiment. However, the light detection pulse PLS is not fed back to the gate of the transistor Trch. At t4, when the control signal XRCG periodically falls, the capacitors CPk1, Ca are restored to the charged level via the transistor Trch.

As a result, when one photon enters the photodiode PD within the period of the cycle CLK, the counter circuit 16 increases the count value by 1. That is, the counter circuit 16 can detect a photon entering the photodiode PD for each cycle CLK.

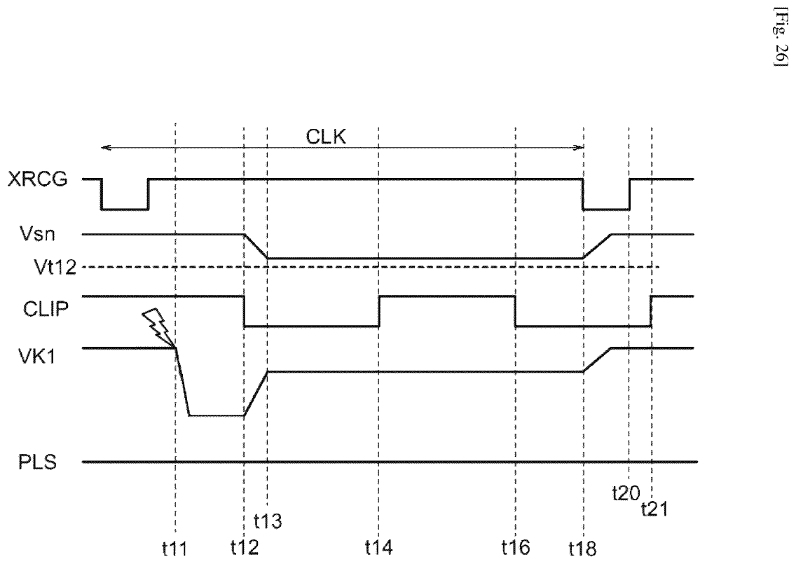

FIG. 26 is a timing diagram illustrating an operation example of the photodetection device according to the sixth embodiment. In FIG. 26, the switch SW1 is in the conductive state, and the capacitance of the sense node SN is (Ca+Cv), which is relatively large. FIG. 26 illustrates a case where one photon enters the photodiode PD in the operation in the high-illuminance mode.

The operation of the pixel P from t11 to t14 may be the same as that in the third embodiment. At t11, when a photon enters the photodiode PD, avalanche breakdown occurs in the photodiode PD, and the cathode voltage VK1 decreases. However, even when the control signal CLIP falls and the transistor Tclip enters the conductive state, the light detection pulse PLS is not generated because the voltage Vsn of the sense node SN does not fall below the threshold Vt12. Thus, even when one photon enters the photodiode PD, the counter circuit 16 does not perform counting.

In a case where the second photon does not enter, the control signal CLIP falls at t16, but the voltage Vsn remains almost unchanged. From t18 to t20, the control signal XRCG falls in the next charging operation, and the capacitors CPK1, Ca, Cv are restored to the charged level via the transistor Trch. At t12, the control signal CLIP is raised. As a result, the state is reset to the state of t11.

In the high-illuminance mode, in a case where two photons enter during the period of the cycle CLK, the operation in the sixth embodiment may be the same as the operation in the third embodiment illustrated in FIG. 12. Therefore, the sixth embodiment can obtain the effects similar to those of the third embodiment. Further, In the sixth embodiment, the sensitivity can be enhanced by setting the charge cycle CLK longer in the low-illuminance mode, and the saturation can be prevented by setting the charge cycle CLK shorter in the high-illuminance mode. This enables the photodetection device 100 to widen the dynamic range and improve the SNR while preventing an increase in the count value.

### Seventh Embodiment

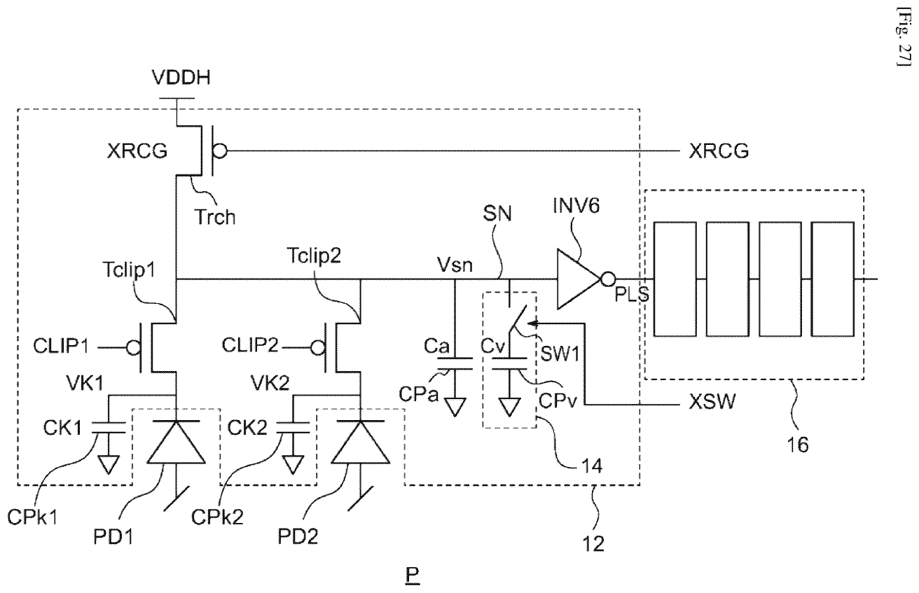

FIG. 27 is a block diagram illustrating an example of an internal configuration of a pixel P according to a seventh embodiment. In the seventh embodiment, the transistor Trch and the switch SW1 are controlled by the vertical selection circuit 30 or the control circuit 70 outside the pixel P. Therefore, the switching between the low-illuminance mode and the high-illuminance mode and the charging timing of the capacitors CPk1, Ca (and Cv) are controlled by the control signals XRCG, XSW from the outside. Other configurations of the seventh embodiment may be similar to those of the fourth embodiment. That is, the seventh embodiment is a combination of the fourth and fifth embodiments. Therefore, the seventh embodiment can obtain the effects similar to those of the fourth and fifth embodiments.

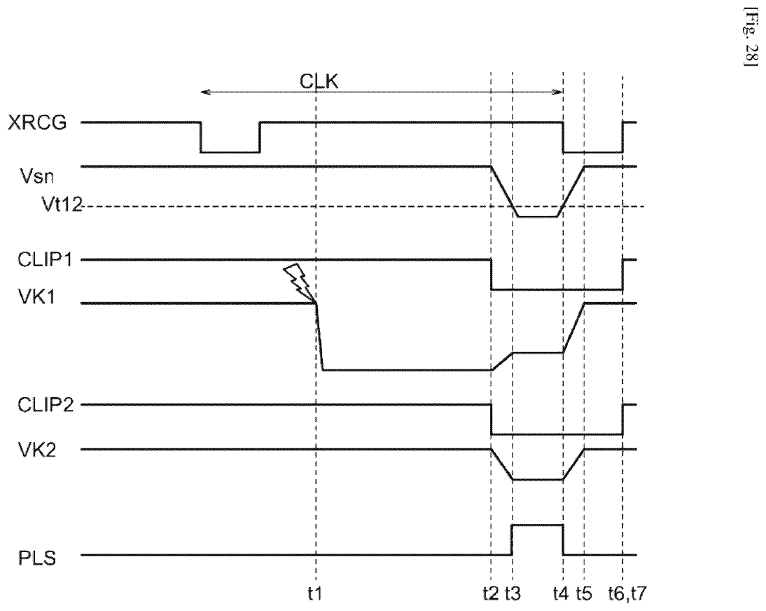

FIGS. 28 and 29 are timing diagrams illustrating an operation example of the photodetection device according to the seventh embodiment. In FIGS. 28 and 29, the switch SW1 is in the non-conductive state, and the capacitance of the sense node SN is Ca, which is relatively small. FIGS. 28 and 29 illustrate the operation in the low-illuminance mode. FIG. 28 illustrates an operation when one photodiode PD1 is detecting a photon. FIG. 29 illustrates an operation when both the photodiodes PD1, PD2 are detecting photons.

The operation from t1 to t1a in each of FIGS. 28 and 29 is basically similar to that in the second embodiment. At this time, the capacitors CPK1, CPk2, Ca are in the charged state. In such a state, the photodiodes PD1, PD2 wait for entry of photons. Note that the transistors Tclip1, Tclip2 are in the non-conductive state with a reverse bias voltage applied to each of the photodiodes PD1, PD2.

### Entry of Photon into Only PD1

As illustrated in FIG. 28, in the seventh embodiment, the vertical selection circuit 30 lowers the control signal XRCG in the cycle CLK to charge the capacitors CPk1, CPk2, Ca via the transistor Trch.

When a photon enters the photodiode PD1 at t1 between the charging of the capacitors CPk1, CPk2, Ca and the next charging, avalanche breakdown occurs in the photodiode PD1, and the cathode voltage VK1 decreases. At this time, since the control signal CLIP1 has risen, the transistor Tclip1 is in the non-conductive state, and the voltage Vsn of the sense node SN has been kept at the charged level.

After the signals CLIP1, CLIP2 fall, the operation of the pixels P from t2 to t7 may be the same as that in the fourth embodiment. However, the light detection pulse PLS is not fed back to the gate of the transistor Trch. At t4, when the control signal XRCG periodically falls, the capacitors CPk1, CPk2, Ca are restored to the charged level via the transistor Trch.

As a result, when one photon enters the photodiode PD1 during the period of the cycle CLK, the counter circuit 16 increases the count value by 1. That is, the counter circuit 16 can detect a photon entering the photodiode PD in each cycle CLK.

Note that the operation of the photodetection device 100 in a case where photons enter only the photodiode PD2 can be easily understood with reference to FIG. 14, and hence the description thereof will be omitted.

### Entry of Photons into Both PD1 and PD2

As illustrated in FIG. 29, when photons enter both the photodiodes PD1, PD2 at t1a and t1b, avalanche breakdown occurs in the photodiodes PD1, PD2, and both the cathode voltages VK1, VK2 decrease. At this time, with the transistors Tclip1, Tclip2 in the non-conductive state, the voltage Vsn of the sense node SN does not decrease.

After the signals CLIP1, CLIP2 fall, the operation of the pixels P from t2 to t7 may be the same as that in the fourth embodiment. However, the light detection pulse PLS is not fed back to the gate of the transistor Trch. At t4, when the control signal XRCG periodically falls, the capacitors CPk1, CPk2, Ca are restored to the charged level via the transistor Trch.

Accordingly, when a photon enters each of the photodiodes PD1, PD2 during the period of the cycle CLK, the counter circuit 16 increases the count value by 1. That is, the counter circuit 16 can detect two photons entering the photodiodes PD1, PD2 in each cycle CLK.

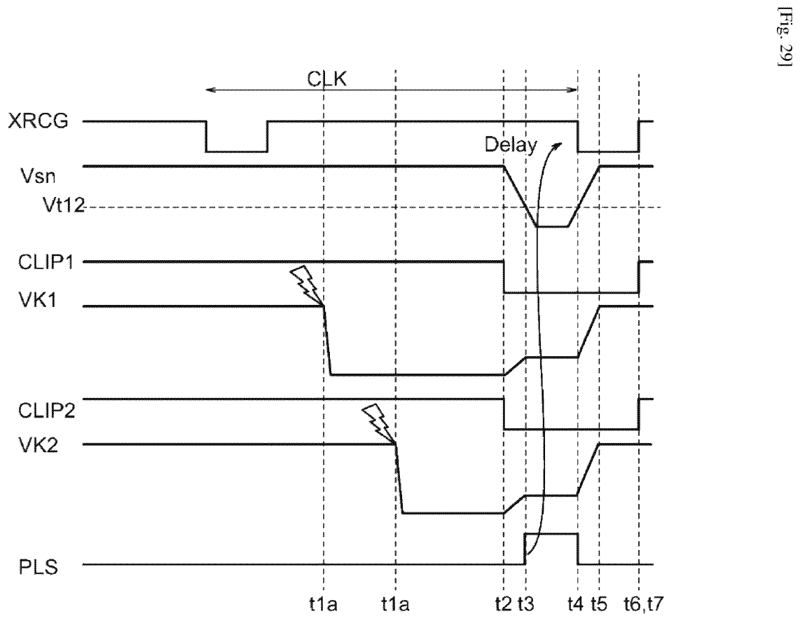

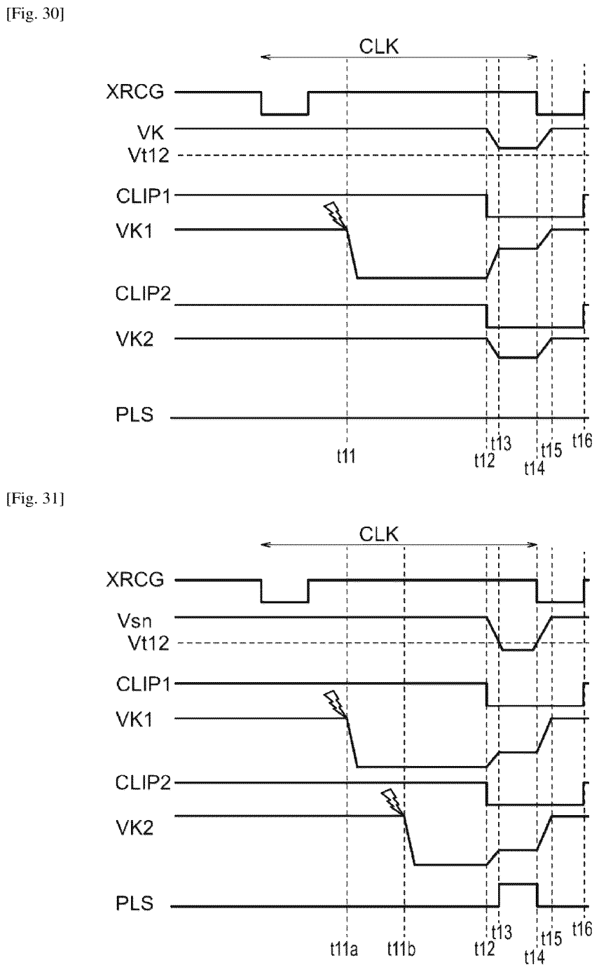

FIGS. 30 and 31 are timing diagrams illustrating an operation example of the photodetection device according to the seventh embodiment. In FIGS. 30 and 31, the switch SW1 is in the conductive state, and the capacitance of the sense node SN is (Ca+Cv), which is relatively large. FIGS. 30 and 31 illustrate operations in the high-illuminance mode. FIG. 30 illustrates an operation when one photodiode PD1 is detecting a photon. FIG. 31 illustrates an operation when both the photodiodes PD1, PD2 are detecting photons.

The operation up to t11 in each of FIGS. 30 and 31 is basically similar to that of the second embodiment. At this time, the capacitors CPK1, CPk2, Ca are in the charged state. In such a state, the photodiodes PD1, PD2 wait for entry of photons. Note that the transistors Tclip1, Tclip2 are in the non-conductive state with a reverse bias voltage applied to each of the photodiodes PD1, PD2.

### Entry of Photon into Only PD1

As illustrated in FIG. 30, in the seventh embodiment, the vertical selection circuit 30 lowers the control signal XRCG in the cycle CLK to charge the capacitors CPK1, CPk2, Ca, Cv via the transistor Trch.

When a photon enters the photodiode PD1 at t11 between the charging of the capacitors CPK1, CPk2, Ca, Cv and the next charging, avalanche breakdown occurs in the photodiode PD1, and the cathode voltage VK1 decreases. At this time, since the control signal CLIP1 has risen, the transistor Tclip1 is in the non-conductive state, and the voltage Vsn of the sense node SN has been kept at the charged level.

After the signals CLIP1, CLIP2 fall, the operation of the pixels P at t12 to t14 may be the same as that in the fourth embodiment. That is, with the switch SW1 in the conductive state, the voltage Vsn of the sense node SN does not fall below the threshold Vt12 as in the fourth embodiment. Thus, even when one photon enters the photodiode PD, the counter circuit 16 does not perform counting.

However, the light detection pulse PLS is not fed back to the gate of the transistor Trch. At t14, when the control signal XRCG periodically falls, the capacitors CPk1, CPk2, Ca, Cv are restored to the charged level via the transistor Trch. As a result, the photodetection device 100 returns to the state before t11.

### Entry of Photons into Both PD1 and PD2

As illustrated in FIG. 31, when photons enter both the photodiodes PD1, PD2 at t11a and t11b, avalanche breakdown occurs in the photodiodes PD1, PD2, and both the cathode voltages VK1, VK2 decrease. At this time, with the transistors Tclip1, Tclip2 in the non-conductive state, the voltage Vsn of the sense node SN does not decrease.

After the signals CLIP1, CLIP2 fall, the operation of the pixels P at t12 to t17 may be the same as that in the fourth embodiment. However, the light detection pulse PLS is not fed back to the gate of the transistor Trch. At t14, when the control signal XRCG periodically falls, the capacitors CPk1, CPk2, Ca, Cv are restored to the charged level via the transistor Trch.

Accordingly, when a photon enters each of the photodiodes PD1, PD2 during the period of the cycle CLK, the counter circuit 16 increases the count value by 1. That is, the counter circuit 16 can detect two photons entering the photodiodes PD1, PD2 in each cycle CLK.

In the high-illuminance mode, in a case where two photons enter during the period of the cycle CLK, the operation in the seventh embodiment may be the same as the operation in the fourth embodiment illustrated in FIG. 15 or 17. Therefore, the seventh embodiment can obtain the effects similar to those of the fourth embodiment. Further, in the seventh embodiment, in the low-illuminance mode, the sensitivity can be enhanced by setting the charge cycle CLK longer, and in the high-illuminance mode, the charge cycle CLK can be set shorter to prevent saturation. This enables the photodetection device 100 to widen the dynamic range and improve the SNR while preventing an increase in the count value.

### Eighth Embodiment

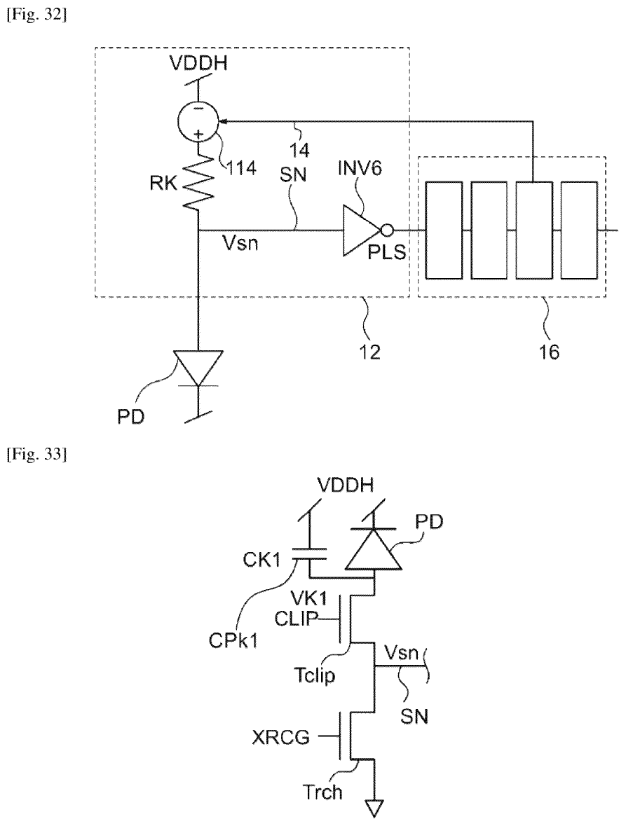

FIG. 32 is a block diagram illustrating an example of an internal configuration of a pixel P according to an eighth embodiment. In the eighth embodiment, the photodiode PD is a dynamic photo diode (DPD). In the DPD, the number of entering photons changes when breakdown occurs according to the forward bias voltage. The anode of the photodiode PD is connected to the sense node SN. The cathode of the photodiode PD is connected to a reference voltage source (e.g., ground).

A power supply circuit 114 applies a forward bias voltage to the photodiode PD. The power supply circuit 114 is connected between the voltage source VDDH and the resistive element RK. The power supply circuit 114 can change the forward bias voltage to be applied to the photodiode PD upon receipt of the feedback signal from the count rate control circuit 14.

In the eighth embodiment, the count rate control circuit 14 may be a wiring connected between the counter circuit 16 and the power supply circuit 114. When a predetermined bit of the counter circuit 16 is inverted, the count rate control circuit 14 can invert a control signal fed back to the power supply circuit 114 to change the voltage of the power supply circuit 114. For example, in a case where the count value is less than a predetermined value, the count rate control circuit 14 sets the forward bias voltage to a first voltage while lowering the control signal. In a case where the count value becomes greater than or equal to the predetermined value, the count rate control circuit 14 raises the control signal to set the forward bias voltage to a second voltage smaller than the first voltage.

The resistive element RK is connected between the count rate control circuit 14 and the anode (sense node SN) of the photodiode PD. As a result, the voltage Vsn of the sense node SN changes due to the breakdown of the photodiode PD caused by entry of light. The counter circuit 16 counts the light detection pulse PLS generated by the breakdown of the photodiode PD. The count rate control circuit 14 controls the forward bias voltage from the power supply circuit according to the count value of the counter circuit 16.

In the eighth embodiment, the capacitor CPv and the switch SW1 are not provided. The control signal fed back from the counter circuit 16 is applied to the power supply circuit 114. In a case where the count value of the counter circuit 16 is less than the predetermined value, the count rate control circuit 14 makes the voltage of the power supply circuit 114, which is applied to the anode of the photodiode PD, relatively high to make the forward bias voltage relatively large. As a result, breakdown occurs in the photodiode PD every time one photon enters thereinto, and the inverter INV6 generates the light detection pulse PLS. In this case, the counter circuit 16 increases the count value by 1 every time one photon is detected.

In a case where the count value of the counter circuit 16 exceeds the predetermined value, the count rate control circuit 14 makes the voltage of the power supply circuit 114, which is applied to the anode of the photodiode PD, relatively low to make the forward bias voltage relatively small. As a result, breakdown occurs in the photodiode PD every time n (n is an integer of 2 or more) photons enters thereinto, and the inverter INV6 generates the light detection pulse PLS. In this case, the counter circuit 16 increases the count value for each breakdown of the photodiode PD, but substantially increases the count value by 1 for each detection of n photons.

As described above, by using the DPD as the photodiode PD and using the count rate control circuit 14 and the power supply circuit 114, it is possible to switch the number of photons for which count value is increased in each of the low-illuminance mode and the high-illuminance mode. Therefore, the eighth embodiment can obtain the effects similar to those of the other embodiments.

Further, according to the eighth embodiment, the number of breakdown times of the photodiode PD and the number of generation times of the light detection pulse PLS decrease in the high-illuminance mode. Therefore, power consumption can be reduced.

### Ninth Embodiment

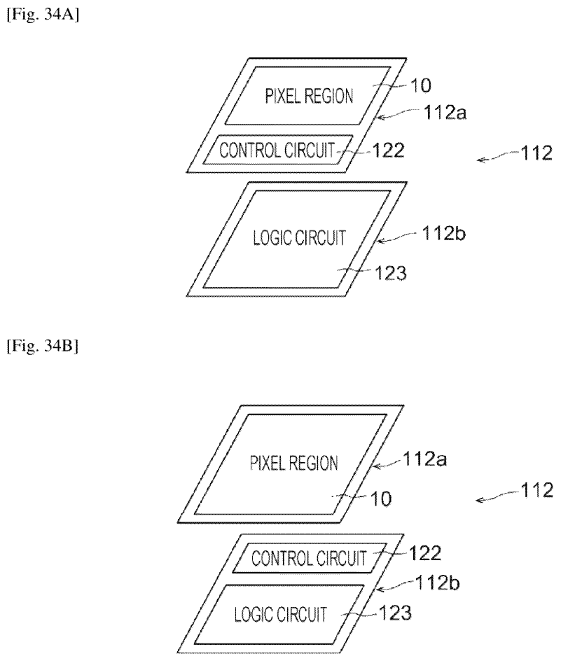

FIG. 33 is a block diagram illustrating a part of an internal configuration example of a pixel P according to a ninth embodiment. In the ninth embodiment, the positional relationship between the photodiode PD and the transistor Trch is opposite to that in the third embodiment. That is, the anode of the photodiode PD is connected to the voltage source VDDH, and the cathode of the photodiode PD is connected to the drain of the transistor Tclip. The capacitor CPk1 is connected in parallel to the photodiode PD. Therefore, one end of the capacitor CPk1 is connected to the voltage source VDDH, and the other end is connected to the drain of the transistor Tclip.

The source of the transistor Tclip is connected to the sense node SN and the drain of the transistor Trch. The transistor Tclip is constituted by an n-type MOSFET, for example.

The drain of the transistor Trch is connected to the sense node SN and the source of the transistor Tclip. The drain of the transistor Trch is connected to a reference voltage source (e.g., ground). The transistor Trch is constituted by an n-type MOSFET, for example.

Other configurations of the ninth embodiment may be the same as those of the third embodiment. The conductivity types of the transistors Tclip, Trch are opposite conductivity types of those of the third embodiment. Therefore, the control signals CLIP, XRCG of the transistors Tclip, Trch are reversed logics from those of the third embodiment.

Even with the configuration of the ninth embodiment, the operation is performed as in the third embodiment, and it is possible to obtain the same effects as those of the third embodiment. Instead of the transistor Tclip, the resistive element RK may be provided between the sense node SN and the photodiode PD. The ninth embodiment can also be applied to other embodiments.

### Chip Stack

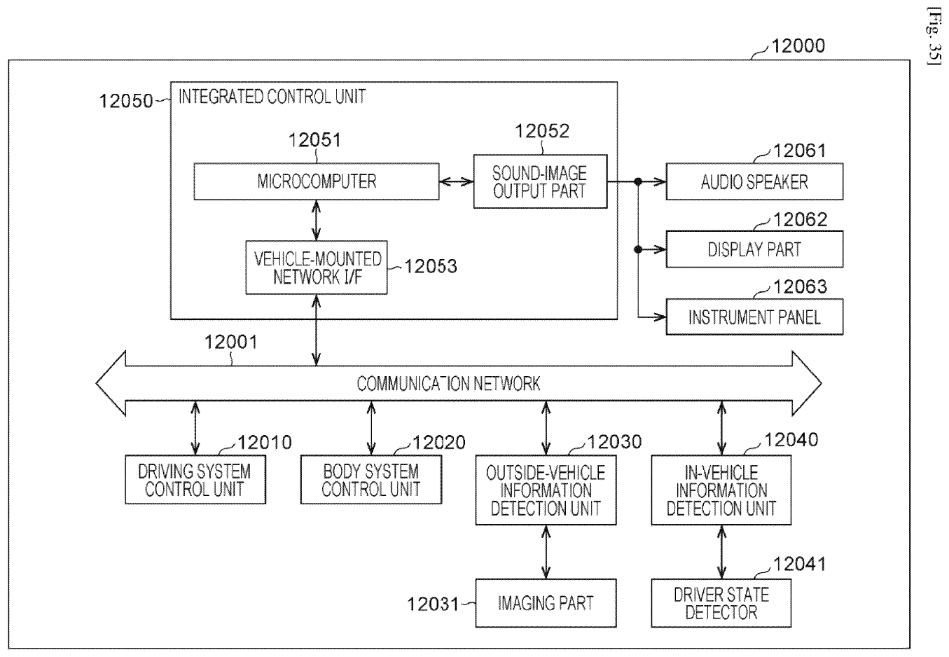

FIGS. 34A and 34B are schematic diagrams illustrating examples of a chip stack configuration of the photodetection device 100. A semiconductor chip 112 is, for example, a stacked chip of an upper substrate 112a and a lower substrate 112b. For example, the upper substrate 112a is provided with a pixel region 10 in which the pixels P are arranged two-dimensionally, and a control circuit 122 that controls the pixels P. The control circuit 122 includes all or some of the vertical selection circuit 30, the signal processing circuit 40, the horizontal selection circuit 50, the output circuit 60, and the control circuit 70. The lower substrate 112b is provided with a logic circuit 123 such as a signal processing circuit that processes a pixel signal output from a pixel. Alternatively, as illustrated in FIG. 34B, only the pixel region 10 may be provided on the upper substrate 112a, and the control circuit 122 and the logic circuit 123 may be provided on the lower substrate 112b.

As described above, in the semiconductor chip 112, one or both of the control circuit 122 and the logic circuit 123 may be provided on the lower substrate 112b different from the upper substrate 112a for the pixel region 10. This enables the chip size to be smaller than a case where the pixel region 10, the control circuit 122, and the logic circuit 123 are arranged in a planar direction on one substrate.

Furthermore, a plurality of divided semiconductor chips is formed and stacked to constitute the pixel region 10. In this case, the chip size can be further reduced.

The upper substrate 112a and the lower substrate 112b may be connected to each other by a through-electrode, or wires may be connected to each other by Cu—Cu bonding.

### Application Example to Mobile Body

The technology according to the present disclosure (present technology) can be applied to various products. For example, the technology according to an embodiment of the present disclosure may also be implemented as a device mounted on any type of mobile body such as an automobile, an electric automobile, a hybrid electric automobile, a motorcycle, a bicycle, a personal mobility, an airplane, a drone, a ship, and a robot.

FIG. 35 is a block diagram illustrating a schematic configuration example of a vehicle control system that is an example of a mobile object control system to which the technology according to the present disclosure can be applied.

A vehicle control system 12000 includes a plurality of electronic control units connected to each other via a communication network 12001. In the example illustrated in FIG. 35, the vehicle control system 12000 includes a driving system control unit 12010, a body system control unit 12020, an outside-vehicle information detection unit 12030, an in-vehicle information detection unit 12040, and an integrated control unit 12050. In addition, a microcomputer 12051, a sound-image output part 12052, and a vehicle-mounted network interface (I/F) 12053 are illustrated as a functional configuration of the integrated control unit 12050.

The driving system control unit 12010 controls the operation of devices related to the driving system of the vehicle according to various kinds of programs. For example, the driving system control unit 12010 functions as a control device for a driving force generation device for generating the driving force of the vehicle, such as an internal combustion engine or a driving motor, a driving force transmitting mechanism for transmitting the driving force to wheels, a steering mechanism for adjusting the steering angle of the vehicle, and a braking device for generating the braking force of the vehicle.

The body system control unit 12020 controls the operation of various kinds of devices provided to a vehicle body according to various kinds of programs. For example, the body system control unit 12020 functions as a control device for a keyless entry system, a smart key system, a power window device, or various kinds of lamps such as a headlamp, a backup lamp, a brake lamp, a turn signal, or a fog lamp. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detection unit 12030 detects information about the outside of the vehicle including the vehicle control system 12000. For example, an imaging part 12031 is connected to the outside-vehicle information detection unit 12030. The outside-vehicle information detection unit 12030 causes the imaging part 12031 to capture an image of the outside of the vehicle, and receives the captured image. On the basis of the received image, the outside-vehicle information detection unit 12030 may perform processing of detecting an object such as a human, a vehicle, an obstacle, a sign, or a character on a road surface, or processing of detecting a distance thereto.

The imaging part 12031 is a photosensor that receives light and outputs an electric signal corresponding to the light reception amount of the light. The imaging part 12031 can output the electric signal as an image, or can output the electric signal as information about a measured distance. In addition, the light received by the imaging part 12031 may be visible light or may be invisible light such as infrared rays.

The in-vehicle information detection unit 12040 detects information about the inside of the vehicle. For example, a driver state detector 12041 for detecting the state of a driver is connected to the in-vehicle information detection unit 12040. The driver state detector 12041, for example, includes a camera that images the driver. On the basis of detection information input from the driver state detector 12041, the in-vehicle information detection unit 12040 may calculate the degree of fatigue of the driver or the degree of concentration of the driver or may determine whether the driver is awake.

The microcomputer 12051 can calculate a control target value for the driving force generation device, the steering mechanism, or the braking device on the basis of the information about the inside or outside of the vehicle, which is obtained by the outside-vehicle information detection unit 12030 or the in-vehicle information detection unit 12040, and can output a control command to the driving system control unit 12010. For example, the microcomputer 12051 can perform cooperative control intended to implement functions of an advanced driver assistance system (ADAS), the functions including collision avoidance or shock mitigation for the vehicle, following traveling based on a following distance, constant vehicle speed traveling, a warning of collision of the vehicle, a warning of deviation of the vehicle from a lane, and the like.

Further, the microcomputer 12051 can perform cooperative control intended for automated driving, in which the vehicle travels in an automated manner without depending on the operation of the driver, or the like, by controlling the driving force generation device, the steering mechanism, the braking device, or the like on the basis of information about the surroundings of the vehicle obtained by the outside-vehicle information detection unit 12030 or the in-vehicle information detection unit 12040.

In addition, the microcomputer 12051 can output a control command to the body system control unit 12020 on the basis of the information about the outside of the vehicle obtained by the outside-vehicle information detection unit 12030. For example, the microcomputer 12051 can perform cooperative control intended to prevent glare by controlling the headlamp so as to change from a high beam to a low beam, for example, according to the position of a preceding vehicle or an oncoming vehicle detected by the outside-vehicle information detection unit 12030.

The sound-image output part 12052 transmits an output signal of at least one of a sound or an image to an output device capable of visually or auditorily notifying an occupant of the vehicle or the outside of the vehicle of information. In the example of FIG. 35, an audio speaker 12061, a display part 12062, and an instrument panel 12063 are illustrated as output devices. The display part 12062 may, for example, include at least one of an on-board display or a head-up display.

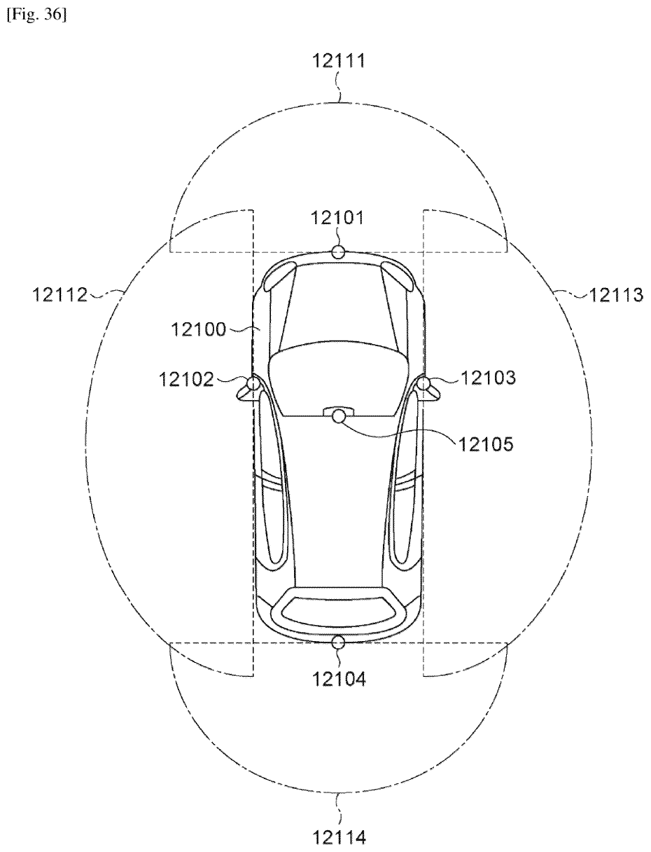

FIG. 36 is a diagram illustrating an example of an installation position of the imaging part 12031.

In FIG. 36, the imaging part 12031 includes imaging parts 12101, 12102, 12103, 12104, 12105.

The imaging parts 12101, 12102, 12103, 12104, 12105 are, for example, disposed at positions on a front nose, side-view mirrors, a rear bumper, and a back door of a vehicle 12100, an upper portion of a windshield within the interior of the vehicle, or some other positions. The imaging part 12101 provided on the front nose and the imaging part 12105 provided in the upper portion of the windshield within the interior of the vehicle mainly obtain the image of the front of the vehicle 12100. The imaging parts 12102, 12103 provided on the side-view mirrors mainly obtain the image of the sides of the vehicle 12100. The imaging part 12104 provided on the rear bumper or the back door mainly obtains the image of the rear of the vehicle 12100. The imaging part 12105 provided in the upper portion of the windshield within the interior of the vehicle is mainly used to detect a preceding vehicle, a pedestrian, an obstacle, a signal, a traffic sign, a lane, or the like.

Note that FIG. 36 illustrates an example of imaging ranges of the imaging parts 12101 to 12104. An imaging range 12111 indicates the imaging range of the imaging part 12101 on the front nose, imaging ranges 12112, 12113 indicate the imaging ranges of the imaging parts 12102 and 12103 on the side-view mirrors, respectively, and an imaging range 12114 indicates the imaging range of the imaging part 12104 on the rear bumper or the back door. The bird's-eye image of the vehicle 12100 as viewed from above is obtained by superimposing pieces of image data captured by the imaging parts 12101 to 12104, for example.

At least one of the imaging parts 12101 to 12104 may have a function of obtaining distance information. For example, at least one of the imaging parts 12101 to 12104 may be a stereo camera including a plurality of imaging elements, or may be an imaging element having pixels for phase difference detection.

For example, the microcomputer 12051 can obtain a distance to each three-dimensional object within the imaging ranges 12111 to 12114 and a temporal change in the distance (a relative speed to the vehicle 12100) on the basis of the distance information obtained from the imaging parts 12101 to 12104, and thereby extract, as the preceding vehicle, especially the nearest three-dimensional object that is on the traveling path of the vehicle 12100 and travels at a predetermined speed (e.g., 0 km/hour or higher) in a direction substantially the same as that of the vehicle 12100. Moreover, the microcomputer 12051 can set an inter-vehicular distance to be ensured in advance from the preceding vehicle and perform automatic brake control (including following stop control), automatic acceleration control (including following start control), or the like. It is thus possible to perform cooperative control intended for automated driving, in which the vehicle travels automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging parts 12101 to 12104, extract the classified three-dimensional object data, and use the extracted three-dimensional object data for automatic avoidance of an obstacle. For example, the microcomputer 12051 identifies obstacles around the vehicle 12100 as obstacles visible to the driver of the vehicle 12100 and obstacles difficult for the driver to view. Then, the microcomputer 12051 determines a collision risk indicating a risk of collision with each obstacle. In a situation in which the collision risk is higher than or equal to a set value and there is thus a possibility of collision, the microcomputer 12051 can outputs a warning to the driver via the audio speaker 12061 or the display part 12062 and perform forced deceleration or avoidance steering via the driving system control unit 12010 to perform driving assistance to avoid collision.

At least one of the imaging parts 12101 to 12104 may be an infrared camera that detects infrared rays. For example, the microcomputer 12051 can recognize a pedestrian by determining whether or not there is a pedestrian in the captured images of the imaging parts 12101 to 12104. The pedestrian is recognized by, for example, a procedure for extracting feature points in the captured images of the imaging parts 12101 to 12104 serving as infrared cameras and a procedure for determining whether or not the object is a pedestrian by performing pattern matching processing on a series of feature points indicating the outline of the object. When the microcomputer 12051 determines that there is a pedestrian in the captured images of the imaging parts 12101 to 12104, and hence recognizes the pedestrian, the sound-image output part 12052 controls the display part 12062 so as to display a square contour line for emphasis superimposed on the recognized pedestrian. Further, the sound-image output part 12052 may also control the display part 12062 so as to display an icon or the like representing the pedestrian at a desired position.

An example of the vehicle control system to which the technology according to the present disclosure can be applied has been described above. The technology according to the present disclosure may be applied to the imaging part 12031, for example, out of the configurations described above.

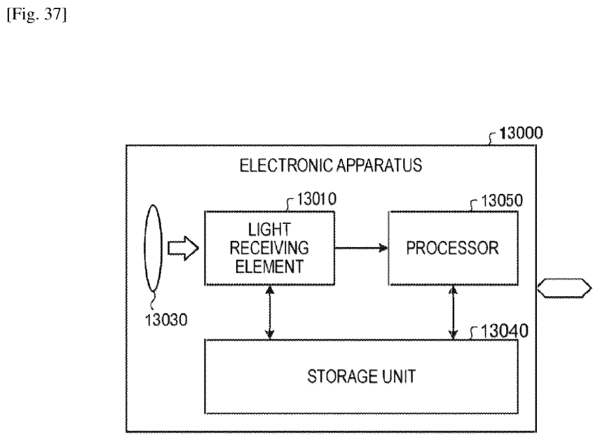

FIG. 37 is a block diagram illustrating a schematic configuration example of an electronic apparatus to which an optical device according to an existing technology is applied. As illustrated in FIG. 37, the electronic apparatus 13000 includes, for example, an imaging lens 13030, an optical device 13010, a storage unit 13040, and a processor 13050.

The imaging lens 13030 is an example of an optical system that condenses incident light and forms an image thereof on a light receiving surface of the optical device 13010. The light receiving surface may be a surface on which pixels are arranged in a matrix in the optical device 13010. The optical device 13010 photoelectrically converts the incident light to generate image data. Further, the optical device 13010 executes predetermined signal processing such as noise removal and white balance adjustment on the generated image data.

The storage unit 13040 includes, for example, a flash memory, a dynamic random access memory (DRAM), a static random access memory (SRAM), or the like, and records image data or the like input from the optical device 13010.

The processor 13050 is configured using, for example, a central processing unit (CPU) or the like, and may include an application processor that executes an operating system, various application software, and the like, a graphics processing unit (GPU), a baseband processor, and the like. The processor 13050 executes various processes as necessary on image data input from the optical device 13010, image data read from the storage unit 13040, or the like, executes display to the user, and transmits the image data to the outside via a predetermined network.

The present technology can also employ the following configurations:
(1)

A light detecting device including:
a first photodiode;
pixel readout circuitry coupled to the first photodiode, the pixel readout circuitry including a recharging circuit coupled to the photodiode and count rate control circuitry coupled between a node and a fixed voltage, the count rate control circuitry including a switch; and
counter circuitry coupled to an output of the pixel readout circuitry,
wherein the switch is configured to switch a first counting mode and a second counting mode.
(2)

The light detecting device according to (1), wherein the first counting mode is a low-illuminance counting mode, and the second counting mode is a high-illuminance counting mode.
(3)

The light detecting device according to (2), wherein a counting rate of the counter in the low-illuminance mode is higher than a counting rate of the counter in the high-luminance mode.
(4)

The light detecting device according to any one of (2) and (3), wherein a charge cycle of the first photodiode in a low-illuminance mode is longer than a charge cycle in the high-illuminance mode, in the low-illuminance mode, the counter circuitry increments a photon count value for each detected photon, in the high-illuminance mode, the counter circuitry increases the photon count value for each of a predetermined plurality of detected photons.
(5)

The light detecting device according to any one of (1) to (4), wherein the pixel readout circuitry includes a resistor coupled between the first photodiode and the node.
(6)

The light detecting device according to any one of (1) to (4), wherein the recharge circuitry includes a transistor connected between a voltage source and the resistor.
(7)

The light detecting device according to (6), wherein the transistor is configured to receive an external control signal that causes the transistor to recharge the first photodiode.
(8)

The light detecting according to any one of (1) to (4), wherein the pixel readout circuitry includes a first transistor coupled between the first photodiode and the node.
(9)

The light detecting device according to (8), wherein the recharge circuitry includes a second transistor connected between a voltage source and the first transistor.
(10)

The light detecting device according to (9), wherein the second transistor is configured to receive an external control signal that causes the second transistor to recharge the first photodiode.
(11)

The light detecting device according to any one of (1) to (10), further comprising a second photodiode coupled to the pixel readout circuitry, wherein the first photodiode is connected in parallel with the second photodiode.
(12)

The light detecting device according to (11), wherein the pixel readout circuitry further includes a first capacitor coupled between the first photodiode and a reference voltage, a second capacitor coupled between the second photodiode and the reference voltage, a first transistor coupled between the first photodiode and the node, and a second transistor coupled between the second photodiode and the node.
(13)

The light detecting device according to any one of (1) to (12), wherein the switch is configured to receive an external control signal that causes the switch to switch between the first counting mode and the second counting mode.
(14)

An electronic apparatus including:
a first photodiode;
pixel readout circuitry coupled to the first photodiode, the pixel readout circuitry including a recharging circuit coupled to the photodiode and count rate control circuitry coupled between a node and a fixed voltage, the count rate control circuitry including a switch; and
counter circuitry coupled to an output of the pixel readout circuitry,
wherein the switch is configured to switch between a first counting mode and a second counting mode.
(15)

The electronic apparatus according to (14), wherein the first counting mode is a low-illuminance counting mode, and the second counting mode is a high-illuminance counting mode.
(16)

The electronic apparatus according to (15), a counting rate of the counter in the low-illuminance mode is higher than a counting rate of the counter in the high-luminance mode.
(17)

The electronic apparatus according to any one of (15) and (16), a charge cycle of the first photodiode in a low-illuminance mode is longer than a charge cycle in the high-illuminance mode, in the low-illuminance mode, the counter circuitry increments a photon count value for each detected photon, in the high-illuminance mode, the counter circuitry increases the photon count value for each of a predetermined plurality of detected photons.
(18)

The electronic apparatus according to any one of (14) to (17), wherein the pixel readout circuitry includes a resistor coupled between the first photodiode and the node.
(19)

The electronic apparatus according to any one of (18), wherein the recharge circuitry includes a transistor connected between a voltage source and the resistor.
(20)

The electronic apparatus according to (19), wherein the transistor is configured to receive an external control signal that causes the transistor to recharge the first photodiode.
(B1) A photodetection device including:
a first photodiode;
a sense node having a voltage that changes due to breakdown of the first photodiode caused by entry of light;
a counter that counts the number of breakdown times of the first photodiode on the basis of the voltage of the sense node; and
a count controller that controls the number of breakdown times by increasing a count value of the counter by 1 according to the count value.
(B2) The photodetection device according to (B1), in which the count controller includes a first capacitor and a switch connected in series between the sense node and a reference voltage source.
(B3) The photodetection device according to (B2), in which the switch is in a non-conductive state in a case where the count value is less than a predetermined value, and the switch is in a conductive state in a case where the count value is greater than or equal to the predetermined value.
(B4) The photodetection device according to (B3), in which
in the case where the switch is in the non-conductive state, the counter increases the count value by 1 every time the first photodiode breaks down, and
in the case where the switch is in the conductive state, the counter increases the count value by 1 every time the first photodiode breaks down n times, where n is an integer of 2 or more.
(B5) The photodetection device according to any one of (B1) to (B4), further including:
a first transistor provided between a voltage source and the sense node and controlled by breakdown of the first photodiode;
a second transistor provided between the first transistor and the sense node and controlled by the breakdown of the first photodiode with a delay relative to the first transistor; and
a second capacitor connected between a reference voltage source and a node between the first transistor and the second transistor.
(B6) The photodetection device according to (B5), in which the count controller controls the value of n by a ratio between a capacitance of the sense node and a capacitance of the node between the first transistor and the second transistor.
(B7) The photodetection device according to any one of (B1) to (B6), further including a pixel region in which a plurality of pixels is arranged,
in which each of the plurality of pixels includes the first photodiode, the counter, and the count controller.
(B8) The photodetection device according to any one of (B1) to (B7), in which the first photodiode is a single photon avalanche diode (SPAD) that undergoes avalanche breakdown once due to entry of one photon.
(B9) The photodetection device according to (B5), in which the count controller is connected in parallel to the second capacitor.
(B10) The photodetection device according to any one of (B1) to (B9), further including a second photodiode provided between the sense node and a reference voltage source.
(B11) The photodetection device according to (B1), in which a cycle of charging the sense node includes a first cycle and a second cycle, longer than the first cycle, in one exposure period of the first photodiode.
(B12) The photodetection device according to any one of (B3) to (B5), in which a cycle of charging the sense node includes a first cycle and a second cycle, longer than the first cycle, in one exposure period of the first photodiode, and
the switch is brought into the conductive state in the first cycle, and the switch is brought into the non-conductive state in the second cycle.
(B13) The photodetection device according to (B2), in which the switch is controlled by a signal from outside the counter and the count controller.
(B14) A photodetection device including:
a first photodiode in which the number of entering photons counted at a time of breakdown changes according to a forward bias voltage;
a power supply circuit that applies the forward bias voltage to the first photodiode;
a sense node having a voltage that changes due to breakdown of the first photodiode caused by entry of light;
a counter that counts the breakdown of the first photodiode; and
a count controller that controls the forward bias voltage from the power supply circuit according to a count value of the counter.
(B15) The photodetection device according to (B14), in which the count controller sets the forward bias voltage to a first voltage in a case where the count value is less than a predetermined value, and the count controller sets the forward bias voltage to a second voltage smaller than the first voltage in a case where the count value is greater than or equal to the predetermined value.
(B16) The photodetection device according to (B15), in which
in a case where the forward bias voltage is the first voltage, the first photodiode breaks down every time one photon enters the photodiode, and
in a case where the forward bias voltage is the second voltage, the first photodiode breaks down every time n photons enter the photodiode, where n is an integer of 2 or more.

Note that the present disclosure is not limited to the above-described embodiments, and various modifications can be made without departing from the gist of the present disclosure. Further, the effects described in the present description are merely examples and are not limited, and other effects may be provided.

It should be understood by those skilled in the art that various modifications, combinations, sub-combinations and alterations may occur depending on design requirements and other factors insofar as they are within the scope of the appended claims or the equivalents thereof.

### REFERENCE SIGNS LIST

P Pixel
PD Photodiode
12 Pixel control circuit
14 Count rate control circuit
16 Counter
Trch, Ts, Ta, Trst Transistor
INV1 to INV7 Inverter
CPs, CPa, CPv, CPk1, CPk2 Capacitor

1. A light detecting device comprising:
a first photodiode;
pixel readout circuitry coupled to the first photodiode, the pixel readout circuitry including a recharging circuit coupled to the photodiode and count rate control circuitry coupled between a node and a fixed voltage, the count rate control circuitry including a switch; and
counter circuitry coupled to an output of the pixel readout circuitry, wherein the switch is configured to switch a first counting mode and a second counting mode.

2. The light detecting device of claim 1, wherein
the first counting mode is a low-illuminance counting mode, and the second counting mode is a high-illuminance counting mode.

3. The light detecting device of claim 2, wherein
a counting rate of the counter in the low-illuminance mode is higher than a counting rate of the counter in the high-luminance mode.

4. The light detecting device of claim 2, wherein
a charge cycle of the first photodiode in a low-illuminance mode is longer than a charge cycle in the high-illuminance mode,
in the low-illuminance mode, the counter circuitry increments a photon count value for each detected photon,
in the high-illuminance mode, the counter circuitry increases the photon count value for each of a predetermined plurality of detected photons.

5. The light detecting device of claim 1, wherein the pixel readout circuitry includes
a resistor coupled between the first photodiode and the node.

6. The light detecting device of claim 5, wherein the recharge circuitry includes a transistor connected between a voltage source and the resistor.

7. The light detecting device of claim 6, wherein the transistor is configured to receive an external control signal that causes the transistor to recharge the first photodiode.

8. The light detecting device of claim 1, wherein the pixel readout circuitry includes
a first transistor coupled between the first photodiode and the node.

9. The light detecting device of claim 8, wherein the recharge circuitry includes a second transistor connected between a voltage source and the first transistor.

10. The light detecting device of claim 9, wherein the second transistor is configured to receive an external control signal that causes the second transistor to recharge the first photodiode.

11. The light detecting device of claim 1, further comprising:
a second photodiode coupled to the pixel readout circuitry, wherein the first photodiode is connected in parallel with the second photodiode.

12. The light detecting device of claim 11, wherein the pixel readout circuitry further includes:
a first capacitor coupled between the first photodiode and a reference voltage,
a second capacitor coupled between the second photodiode and the reference voltage,
a first transistor coupled between the first photodiode and the node, and
a second transistor coupled between the second photodiode and the node.

13. The light detecting device of claim 1, wherein the switch is configured to receive an external control signal that causes the switch to switch between the first counting mode and the second counting mode.

14. An electronic apparatus comprising:
a first photodiode;
pixel readout circuitry coupled to the first photodiode, the pixel readout circuitry including a recharging circuit coupled to the photodiode and count rate control circuitry coupled between a node and a fixed voltage, the count rate control circuitry including a switch; and
counter circuitry coupled to an output of the pixel readout circuitry,
wherein the switch is configured to switch between a first counting mode and a second counting mode.

15. The electronic apparatus of claim 14, wherein
the first counting mode is a low-illuminance counting mode, and
the second counting mode is a high-illuminance counting mode.

16. The electronic apparatus of claim 15, wherein
a counting rate of the counter in the low-illuminance mode is higher than a counting rate of the counter in the high-luminance mode.

17. The electronic apparatus of claim 15, wherein
a charge cycle of the first photodiode in a low-illuminance mode is longer than a charge cycle in the high-illuminance mode,
in the low-illuminance mode, the counter circuitry increments a photon count value for each detected photon,
in the high-illuminance mode, the counter circuitry increases the photon count value for each of a predetermined plurality of detected photons.

18. The light detecting device of claim 14, wherein the pixel readout circuitry includes
a resistor coupled between the first photodiode and the node.

19. The light detecting device of claim 18, wherein the recharge circuitry includes a transistor connected between a voltage source and the resistor.

20. The light detecting device of claim 19, wherein the transistor is configured to receive an external control signal that causes the transistor to recharge the first photodiode.
